(19) United States
(12) Patent Application Publication
(10) Pub. No.: US 2025/0365099 A1
(43) Pub. Date: Nov. 27, 2025

(54) ELECTRONIC DEVICE AND METHOD FOR PROCESSING RECEIVED SIGNAL IN WIRELESS COMMUNICATION SYSTEM

(71) Applicant: Samsung Electronics Co., Ltd., Suwon-si (KR)

(72) Inventors: Hyuntack LIM, Suwon-si (KR); Pilsung KWON, Suwon-si (KR); Hayoung YANG, Suwon-si (KR); Joohyun LEE, Suwon-si (KR)

(21) Appl. No.: 19/295,186

(22) Filed: Aug. 8, 2025

Related U.S. Application Data
(63) Continuation of application No. PCT/KR2024/000727, filed on Jan. 15, 2024.

(30) Foreign Application Priority Data
Feb. 8, 2023 (KR) 10-2023-0017066
Mar. 10, 2023 (KR) 10-2023-0031818

(51) Int. Cl. H04L 1/1812; H04L 1/00

(52) U.S. Cl. CPC H04L 1/1819; H04L 1/0009

(57) ABSTRACT

A method performed by an electronic device is provided. The method includes receiving a first signal related to an initial transmission of a transport block, based on a failure to decode the first signal, storing first data related to the first signal in a soft buffer of the electronic device, receiving a second signal related to a retransmission of the transport block, storing second data related to the second signal in the soft buffer, identifying, among the soft buffer, a first area for the first data and a second area for the second data, distinguished from an area in which data is not stored, as a decoding area, and based on the decoding area, performing decoding of first combined data obtained based on combining the first data and the second data.

### CROSS-REFERENCE TO RELATED APPLICATION(S)

This application is a continuation application, claiming priority under 35 U.S.C. § 365 (c), of an International application No. PCT/KR2024/000727, filed on Jan. 15, 2024, which is based on and claims the benefit of a Korean patent application number 10-2023-0017066, filed on Feb. 8, 2023, in the Korean Intellectual Property Office, and of a Korean patent application number 10-2023-0031818, filed on Mar. 10, 2023, in the Korean Intellectual Property Office, the disclosure of each of which is incorporated by reference herein in its entirety.

### BACKGROUND

### 1. Field

The disclosure relates to a wireless communication system. More particularly, the disclosure relates to an electronic device and a method for processing a received signal in the wireless communication system.

### 2. Description of Related Art

In a communication or broadcasting system, link performance may be significantly degraded by various noise, fading phenomena, and inter-symbol interference (ISI) of a channel. Therefore, to implement high-speed digital communication or broadcasting systems that require high data throughput and reliability, such as next-generation mobile communication, digital broadcasting, and mobile Internet, it is necessary to develop a technology to overcome the noise, the fading and the inter-symbol interference (ISI). Recently, as part of research to overcome the noise, and the like, research on an error-correcting code has been actively conducted as a method to increase reliability of communication by efficiently restoring information distortion.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device and a method for processing a received signal in the wireless communication system.

Additional aspects will be set forth in part in the description which follows and, in part, will be apparent from the description, or may be learned by practice of the presented embodiments.

In accordance with an aspect of the disclosure, a method performed by an electronic device is provided. The method includes receiving a first signal related to an initial transmission of a transport block, based on a failure to decode the first signal, storing first data related to the first signal in a soft buffer of the electronic device, receiving a second signal related to a retransmission of the transport block, storing second data related to the second signal in the soft buffer, identifying, among the soft buffer, a first area for the first data and a second area for the second data, distinguished from an area in which data is not stored, as a decoding area, and based on the decoding area, performing decoding of first combined data obtained based on combining the first data and the second data.

In accordance with another aspect of the disclosure, an electronic device is provided. The electronic device includes memory, including one or more storage media, storing instructions, a transceiver, and at least one processor communicatively coupled to the memory and the transceiver receive a first signal related to an initial transmission of a transport block, based on a failure to decode the first signal, store first data related to the first signal in a soft buffer of the electronic device, receive a second signal related to a retransmission of the transport block, store second data related to the second signal in the soft buffer, identify, among the soft buffer, a first area for the first data and a second area for the second data, distinguished from an area in which data is not stored, as a decoding area, and based on the decoding area, perform decoding of first combined data obtained based on combining the first data and the second data.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a structural diagram of a systematic low density parity check (LDPC) codeword according to an embodiment of the disclosure;

FIG. 2 is a diagram illustrating a representation method of a graph of an LDPC code according to an embodiment of the disclosure;

FIGS. 3A and 3B are diagrams illustrating a cycle characteristic of a quasi-cyclic (QC)-LDPC code according to various embodiments of the disclosure;

FIG. 4 is a block diagram of a transmission device according to an embodiment of the disclosure;

FIG. 5 is a block diagram of a reception device according to an embodiment of the disclosure;

FIGS. 6A and 6B are message structure diagrams indicating a message passing operation at an arbitrary check node and a variable node for LDPC decoding according to various embodiments of the disclosure;

FIG. 7 is a block diagram illustrating a configuration of an LDPC encoding unit according to an embodiment of the disclosure;

FIG. 8 is a block diagram illustrating a configuration of a decoding device according to an embodiment of the disclosure;

FIG. 9 indicates a functional configuration of an LDPC decoding unit according to an embodiment of the disclosure;

FIG. 10 illustrates an operation flow for LDPC decoding of an LDPC decoding device according to an embodiment of the disclosure;

FIG. 11 illustrates an operation flow for decoding based on an LDPC and cyclic redundancy check (CRC) code of an LDPC decoding device according to an embodiment of the disclosure;

FIGS. 12A and 12B illustrate an operation of a base station and a terminal for a hybrid automatic repeat request (HARQ) technique according to various embodiments of the disclosure;

FIG. 13 illustrates a transceiver function block according to an IR-HARQ technique according to an embodiment of the disclosure;

FIG. 14 illustrates an operation for reading and writing HARQ log likelihood ratio (LLR) data stored in HARQ LLR memory in a circular buffer according to an embodiment of the disclosure;

FIG. 15 illustrates reading and writing a partial area of HARQ LLR memory in a circular buffer according to an embodiment of the disclosure;

FIGS. 16A and 16B illustrate parameters for identifying a position of HARQ LLR data according to various embodiments of the disclosure;

FIG. 17 illustrates a change in a data rate according to a partial HARQ LLR input/output technique according to an embodiment of the disclosure;

FIG. 18 illustrates a flowchart related to an operation of an electronic device for a partial HARQ LLR input/output technique according to an embodiment of the disclosure; and

FIG. 19 illustrates a functional configuration of an electronic device according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In various embodiments of the disclosure described below, a hardware approach will be described as an example. However, since the various embodiments of the disclosure include technology that uses both hardware and software, the various embodiments of the disclosure do not exclude a software-based approach.

A term referring to a signal (e.g., signal, information, symbol, message, signaling, reference signal (RS), data), a term referring to a resource (e.g., symbol, slot, subframe, radio frame, subcarrier, resource element (RE), resource block (RB), bandwidth part (BWP), occasion), a term for a calculation state (e.g., step, operation, procedure), a term referring to data (e.g., packet, user stream, information, bit, symbol, codeword), a term referring to a channel, a term referring to a network entity, a term referring to a component of a device, and the like, that are used in the following description, are exemplified for convenience of explanation. Therefore, the disclosure is not limited to terms to be described below, and another term having an equivalent technical meaning may be used.

In addition, in the disclosure, the term ‘greater than’ or ‘less than’ may be used to determine whether a particular condition is satisfied or fulfilled, but this is only a description to express an example and does not exclude description of ‘greater than or equal to’ or ‘less than or equal to’. A condition described as ‘greater than or equal to’ may be replaced with ‘greater than’, a condition described as ‘less than or equal to’ may be replaced with ‘less than’, and a condition described as ‘greater than or equal to and less than’ may be replaced with ‘greater than and less than or equal to’. In addition, hereinafter, ‘A’ to ‘B’ refers to at least one of elements from A (including A) to B (including B). Hereinafter, ‘C’ and/or ‘D’ means including at least one of ‘C’ or ‘D’, that is, {'C′, ‘D’, and ‘C’ and ‘D’}.

A low density parity check (hereinafter, LDPC) code, first introduced by Gallager in the 1960s, has long been forgotten due to its complexity, which is difficult to implement at the technology level at the time. However, as a turbo code proposed by Berru, Glavieux, and Thitimajshima in 1993 showed performance close to a channel capacity of Shannon, many studies on iterative decoding and graph-based channel coding were conducted as many interpretations for the turbo code's performance and characteristics were made. As a result of this, a re-study of the LDPC code was conducted in the late 1990s, and it was discovered that the LDPC code also had a performance close to the channel capacity of Shenon when it was decoded by applying iterative decoding based on a sum-product algorithm on a Tanner graph corresponding to the LDPC code.

The LDPC code is generally defined as a parity-check matrix and may be represented by using a bipartite graph collectively referred to as the Tanner graph. In general, the LDPC code is a kind of parity check code, which is called a ‘low-density’ parity check code since it has a character that a ratio (i.e., density) of the number of 1 in the parity check matrix with respect to a case in which a length is very long, is very low. Therefore, for convenience, techniques proposed based on the LDPC code in the disclosure may be easily extended with respect to a general parity check matrix code.

It should be appreciated that the blocks in each flowchart and combinations of the flowcharts may be performed by one or more computer programs which include computer-executable instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU) (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

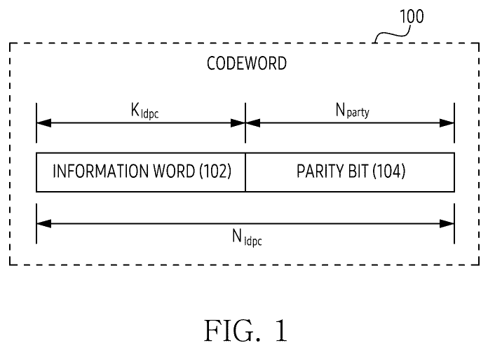

FIG. 1 is a structural diagram of a systematic low density parity check (LDPC) codeword according to an embodiment of the disclosure.

An LDPC encoding process may be performed by a transmission device performing channel coding. An LDPC decoding process may be performed by a reception device that decodes channel coding. Hereinafter, the transmission device may be referred to as an LDPC encoding device, and the reception device may be referred to as an LDPC decoding device.

Referring to FIG. 1, the LDPC encoding device receives an information word 102 configured with K_{ldpc} bits or symbols, performs encoding, and then generates a codeword 100 configured with N_{ldpc} bits or symbols. For convenience of description below, it is assumed that the codeword 100 configured with N_{ldpc} bits is generated by receiving the information word 102 including K_{ldpc}bits. For example, when the information word I [i₀, i₁, i₂, . . . , i_{K}_{_{ldpc}}₋₁] 102, which is K_{ldpc} input bits, is LDPC-encoded, the codeword c=[c₀, c₁, c₂, c₃, . . . , c_{N}_{_{ldpc}}₋₁] 100 is generated. For example, the information word and the codeword are a bit stream configured with a plurality of bits, and an information word bit and a codeword bit mean each bit configuring the information word and the codeword. In general, in a case that an LDPC encoding bit includes an information word, such as, C=[c₀, c₁, c₂, . . . , c_{N}_{_{ldpc}}₋₁]=[i₀, i₁, i₂, . . . , i_{K}_{_{ldpc}}₋₁, p₀, p₁, p₂, . . . , p_{N}_{_{ldpc}}_{-K}_{_{ldpc}}₋₁], it is called a systematic code. Herein, P=[p₀, p₁, p₂, . . . , p_{N}_{_{ldpc}}_{-K}_{_{ldpc}}₋₁] is a parity bit 104, and the number of parity bits N_{parity} may be indicated as N_{parity}=N_{ldpc}−K_{ldpc}.

LDPC encoding is a type of linear block code and includes a process of determining a codeword that satisfies a condition shown in Equation 1 below. LDPC decoding may be understood as a process of deriving a codeword (or an information word) that satisfies the condition shown in Equation 1 below.

$$H \cdot {c}^{T} = [ \begin{matrix}{h}_{1} & {h}_{2} & {h}_{3} & ⋯ & {h}_{{N}_{ldpc} - 1}\end{matrix} ] \cdot {c}^{T} = {\sum }_{i = 0}^{{N}_{ldpc}} {c}_{i} \cdot {h}_{i} = 0 \qquad Equation 1$$

Herein, it is c=[c₀, c₁, c₂, . . . , c_{N}_{_{ldpc}}₋₁].

In Equation 1, H means a parity check matrix, c means a codeword, cᵢ means an i-th bit of the codeword, and N_{ldpc} means a length of LDPC codeword. Herein, hᵢ means an i-th column of the parity check matrix H.

The parity check matrix H is configured with N_{ldpc} columns equal to the number of bits of the LDPC codeword. Since Equation 1 means that a sum of products of the i-th column hᵢ and the i-th codeword bit cᵢ of the parity check matrix becomes ‘0’, the i-th column hᵢ means that it is related to the i-th codeword bit cᵢ.

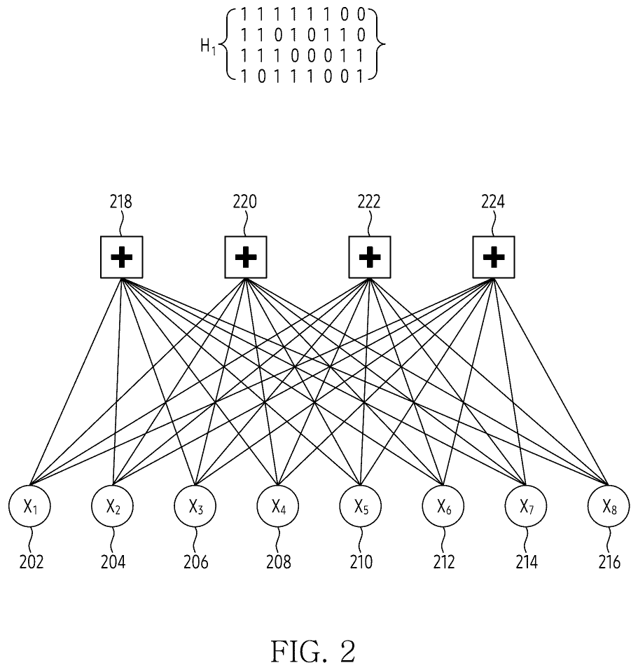

FIG. 2 is a diagram illustrating a representation method of a graph of an LDPC code according to an embodiment of the disclosure.

The representation method of the graph of the LDPC code will be described with reference to FIG. 2.

FIG. 2 is a diagram illustrating an example of a parity check matrix H₁ of an LDPC code configured with 4 rows and 8 columns and a Tanner graph representation thereof. Referring to FIG. 2, since there are 8 columns of the parity check matrix H1, a codeword of length 8 is generated, and a code generated through H₁ means the LDPC code, and each column corresponds to the encoded 8 bits.

Referring to FIG. 2, the Tanner graph of the LDPC code that encodes and decodes based on the parity check matrix H₁, is configured with 8 variable nodes (VN), that is, x1 202, x2 204, x3 206, x4 208, x5 210, x6 212, x7 214, and x8 216, and 4 check nodes (CN) 218, 220, 222, and 224. Herein, the i-th column and the j-th row of the parity check matrix H₁ of the LDPC code correspond to a variable node xᵢ and the j-th check node, respectively. In addition, a value of 1 at a point where the i-th column and j-th row of the parity check matrix H₁ of the LDPC code intersect, that is, a non-zero value, means that there is an edge connecting the variable node xi and the j-th check node on the Tanner graph as shown in FIG. 2.

In the Tanner graph of the LDPC code, a degree of the variable node and the check node means the number of edges connected to each node, which is equal to the number of non-zero entries in a column or a row corresponding to a corresponding node in the parity check matrix of the LDPC code. For example, in FIG. 2, the degree of the variable nodes x1 202, x2 204, x3 206, x4 208, x5 210, x6 212, x7 214, and x8216 becomes 4, 3, 3, 2, 2, 2, 2, and 2, and the degree of check nodes 218, 220, 222, and 224 becomes 6, 5, 5, and 5, respectively. Furthermore, the number of non-zero entries in each column of the parity check matrix H₁ of FIG. 2 corresponding to the variable node of FIG. 2 is in order with the above-described degrees 4, 3, 3, 2, 2, 2, 2, and the number of non-zero entries in each row of the parity check matrix Hi of FIG. 2 corresponding to the check nodes of FIG. 2 is in order with the above-described degrees 6, 5, 5, and 5. For this reason, the degree of each variable node is also called a column degree or a column weight, and the degree of the check node is also called a row degree or a row weight.

In summary, the degree in the parity check matrix of the LDPC code means the number of non-zero entries in a column or row. In addition, the number of non-zero entries in one column in the parity check matrix may be represented as a degree of a corresponding column or a column weight, and the number of non-zero entries in one row may be represented as a degree of a corresponding row or a row weight. In addition, entries of the parity check matrix or an edge on the Tanner graph may be hardware-connected inside a variable node processor (VNU) or a check node processor (CNU) in an LDPC decoder, and may be represented differently in various ways, such as a line, a connection line, an edge, an interconnection network, and a shift network. These interconnection networks are used to input and output appropriate values for LDPC decoding between node processors of the LDPC decoder.

The LDPC decoding device may receive and obtain a codeword, and decode the codeword to obtain an information word. In this case, the LDPC-encoded codeword may be decoded using an iterative decoding algorithm based on a sum-product algorithm on the bipartite graph listed in FIG. 2. Herein, the sum-product algorithm is a type of message passing algorithm, and the message passing algorithm indicates an algorithm that exchanges messages through an edge on a bipartite graph, and calculates and updates an output message from messages inputted to the variable node or the check node.

Herein, the LDPC decoding device may determine a value of the i-th encoding bit based on the message of the i-th variable node. The value of the i-th encoding bit may be determined by a hard decision or a soft decision. For example, both the hard decision method and the soft decision method are applicable to LDPC decoding. Therefore, performance of cᵢ, which is the i-th bit of the LDPC codeword, corresponds to performance of the i-th variable node of the Tanner graph, and it may be determined by a position and the number of 1 in the i-th column of the parity check matrix. In other words, performance of the N_{ldpc} codeword bits of the codeword may be determined by a position and the number of 1 of the parity check matrix, and it means that performance of the LDPC code is greatly influenced by the parity check matrix. Therefore, in order to design an LDPC code with excellent performance, a method of designing a good parity check matrix is needed.

For ease of implementation, the parity check matrix used in a communication and broadcasting system typically uses a quasi-cyclic LDPC code (or QC-LDPC code, hereinafter referred to as QC-LDPC code) that uses a parity check matrix in a form of quasi-cyclic (QC).

The QC-LDPC code is characterized by having a parity check matrix configured with a 0 matrix or circulant permutation matrices in a form of a small quadrate matrix. In this case, a permutation matrix means a matrix in which each row or column includes only one of 1, and all remaining entries are 0. In addition, the circulant permutation matrix means a matrix in which each entry of an identity matrix is circular shifted to the right or left.

Hereinafter, the QC-LDPC code will be described below.

First, as shown in Equation 2, a circulant permutation matrix P=(P_{i,j}) of L×L size is defined. Herein, P_{i,j} means an entry of the i-th row and the j-th column in the matrix P (0≤i, j<L).

$${P}_{i , j} = \{ \begin{matrix}1 & if i + 1 ≡ j mod L \\ 0 & otherwise\end{matrix} . \qquad Equation 2$$

For the permutation matrix P defined as above, Pⁱ (0≤i<L) is a circulant permutation matrix in which each entry of an identity matrix of LXL size is in a form circular shifted in the right direction by i times.

The parity check matrix H of the QC-LDPC code may be represented in a form of Equation 3 below.

$$H = [ \begin{matrix}{P}^{{a}_{11}} & {P}^{{a}_{12}} & ⋯ & {P}^{{a}_{1 n}} \\ {P}^{{a}_{21}} & {P}^{{a}_{22}} & ⋯ & {P}^{{a}_{2 n}} \\ ⋮ & ⋮ & ⋱ & ⋮ \\ {P}^{{a}_{m 1}} & {P}^{{a}_{m 2}} & ⋯ & {P}^{{a}_{mn}}\end{matrix} ] . \qquad Equation 3$$

In a case that P⁻¹ is defined as a 0-matrix of L×L size, each exponent a_{i,j} of the circulant permutation matrix or the 0-matrix in Equation 3 has one of {−1, 0, 1, 2, . . . , L−1} values. In addition, it may be seen that the parity check matrix H of Equation 3 has mL×nL size since it has n column blocks and m row blocks.

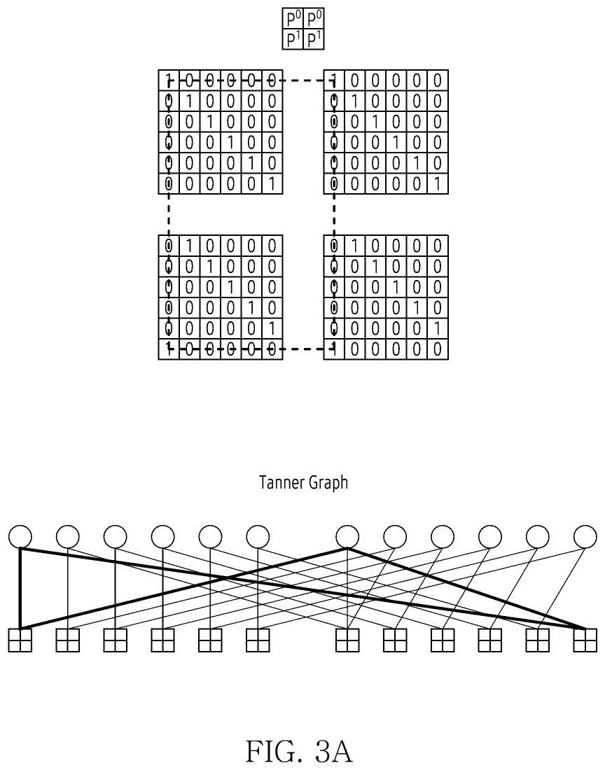

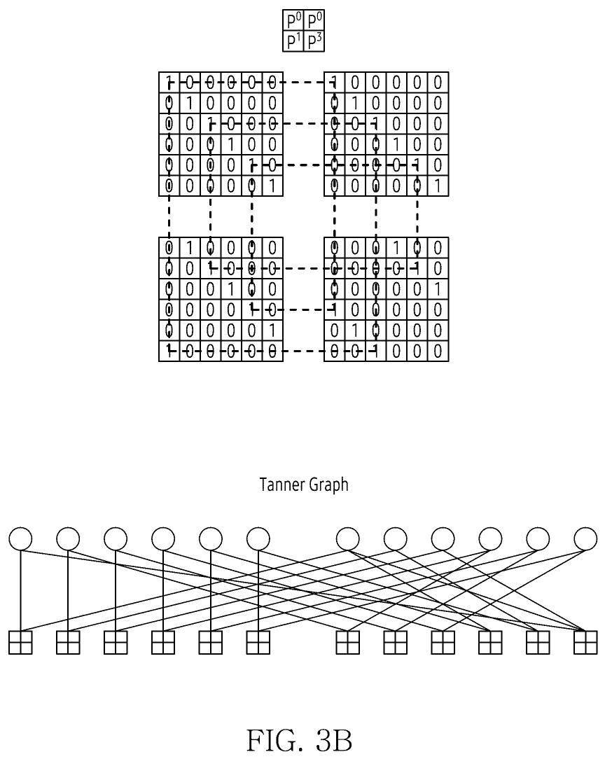

FIGS. 3A and 3B are diagrams for explaining a cycle characteristic of a quasi-cyclic (QC)-LDPC code according to various embodiments of the disclosure.

Referring to FIGS. 3A and 3B, it is identified that a matrix H having a size of 12×12 may be simplified into in a form of 2×2 having a permutation matrix P as an entry shown in Equation 3.

When the parity check matrix of Equation 3 has a full rank, it is obvious that a size of an information word bit of the QC-LDPC code corresponding to the parity check matrix becomes (n−m)L. For convenience, (n−m) column blocks corresponding to the information word bit are called an information word column block, and m column blocks corresponding to remaining parity bits are called a parity column block. When the parity check matrix of Equation 3 does not have a full rank, the information word bit becomes greater than (n−m)L.

Typically, a binary matrix of m×n size obtained by replacing each circulant permutation matrix and 0-matrix by 1 and 0 in the parity check matrix of Equation 3 may be referred to as a mother matrix or a base matrix M(H) of the parity check matrix H. An integer matrix of m×n size obtained by selecting an exponent of each circulant permutation matrix or 0-matrix as shown in Equation 4 may be referred to as an exponent matrix E(H) of the parity check matrix H.

$$E ( H ) = [ \begin{matrix}{a}_{11} & {a}_{12} & ⋯ & {a}_{1 n} \\ {a}_{21} & {a}_{22} & ⋯ & {a}_{2 n} \\ ⋮ & ⋮ & ⋱ & ⋮ \\ {a}_{m 1} & {a}_{m 2} & ⋯ & {a}_{mn}\end{matrix} ] \qquad Equation 4$$

As a result, since one integer included in the exponent matrix corresponds to the circulant permutation matrix and the 0-matrix in the parity check matrix, the exponent matrix may be represented as sequences configured with integers for convenience. In general, the parity check matrix may be represented not only as the exponent matrix but also by various sequences that may represent the same characteristic algebraically. In the disclosure, for convenience, the parity check matrix is represented as an exponent matrix or a sequence indicating a position of 1 in the parity check matrix, and the like, but since there are various sequence notation methods that may distinguish a position of 1 or 0 included in the parity check matrix, it may be represented in a form of various sequences indicating the same effect algebraically without being limited to the method represented in the present specification. The sequence may be referred to in various methods, such as an LDPC sequence or an LDPC code sequence or an LDPC matrix sequence or a parity check matrix sequence, and the like, to distinguish it from another sequence.

Additionally, LDPC encoding and decoding may be performed by directly generating a parity check matrix on the device, but LDPC encoding and decoding may also be performed using an exponent matrix or sequence that has the same effect algebraically as the parity check matrix according to a characteristic of the implementation. Therefore, although the disclosure describes encoding and decoding using the parity check matrix for convenience, it is noted that it may be implemented in various ways to obtain the same effect as the parity check matrix on an actual device. In other words, embodiments are described as encoding and decoding using the parity check matrix, but this may include using other information (e.g., a matrix or sequence including corresponding information) that may replace the parity check matrix, in addition to directly generating the parity check matrix.

For reference, the algebraically same effect means that two or more different expressions may be explained or transformed to be perfectly identical between each other logically or mathematically.

Although only one circulant permutation matrix corresponding to one block has been described in the disclosure for convenience, the same disclosure may be applied even when a plurality of circulant permutation matrices are included in one block. For example, when a position of one of the i-th row block and the j-th column block is included as a sum of two circulant permutation matrices

$${P}^{{a}_{ij}^{( 1 )}} , {P}^{{a}_{ij}^{( 2 )}} ,$$

as shown in Equation 5 below, the exponent matrix may be indicated as Equation 6. Referring to Equation 6, it may be seen that it is a matrix in which two integers correspond to the i-th row and j-th column corresponding to a row block and a column block including a sum of the plurality of circulant permutation matrices.

$$H = [ \begin{matrix}⋱ & & & ⋰ \\ & {P}^{{a}_{ij}^{( 1 )}} + {P}^{{a}_{ij}^{( 2 )}} & & \\ & & & \\ ⋰ & & & ⋱\end{matrix} ] \qquad Equation 5$$

$$E ( H ) = [ \begin{matrix}⋱ & & & ⋰ \\ & ( {a}_{ij}^{( 1 )} , {a}_{ij}^{( 2 )} ) & & \\ & & & \\ ⋰ & & & ⋱\end{matrix} ] \qquad Equation 6$$

As in the above embodiment of the disclosure, generally, in the QC-LDPC code, the plurality of circulant permutation matrices may correspond to one row block and one column block in the parity check matrix, but in the disclosure, for convenience, only a case where one circulant permutation matrix corresponds to one block is described. However, embodiments of the disclosure are not limited thereto. For reference, a matrix of L×L size in which the plurality of circulant permutation matrices overlap in one row block and column block is called a circulant matrix or a circulant.

On the other hand, the mother matrix or the basic matrix for the parity check matrix and the exponent matrix of Equations 5 and 6 refers to a binary matrix obtained by replacing each circulant permutation matrix and 0-matrix by 1 and 0, respectively, similar to the definition used in Equation 3, and a sum of the plurality of circulant permutation matrices (i.e., circulant matrix) included in one block is also simply replaced by 1.

Since the performance of the LDPC code is determined by the parity check matrix, it is required to design the parity check matrix for the LDPC code with excellent performance. In addition, LDPC encoding or decoding methods capable of supporting various input lengths and code rates are required.

Lifting is a method used not only for efficient design of the QC-LDPC code, but also for generating parity check matrices of various lengths from a given exponent matrix or for generating the LDPC codeword. In other words, lifting refers to a method that is applied to efficiently design a very large parity check matrix by setting an L value that determines a size of the circulant permutation matrix or 0-matrix, from a given small mother matrix according to a specific rule, or a method of generating a parity check matrix or LDPC codeword of various lengths by applying an appropriate L value to the given exponent matrix or a corresponding sequence. According to an embodiment of the disclosure, the appropriate L value may mean a Z value of embodiments to be described below in the disclosure.

A characteristic of the QC-LDPC code designed through an existing lifting method and such lifting are briefly described with reference to the following reference [Myung2006].

Reference [Myung2006]

S. Myung, K. Yang, and Y. Kim, “Lifting Methods for Quasi-Cyclic LDPC Codes,” IEEE Communications Letters. vol. 10, pp. 489-491, June 2006.

First, when LDPC code C₀ is given, S QC-LDPC codes to be designed through the lifting method are C₁, . . . , C_{S}, and a value corresponding to a size of a row block and a column block of a parity check matrix of each QC-LDPC code are Lₖ. Herein, C₀ corresponds to the smallest LDPC code having a mother matrix of C₁, . . . , C_{S} codes as a parity check matrix, and an L₀ value corresponding to the size of the row block and column block is 1. In addition, for convenience, a parity check matrix Hₖ of each code Cₖ has an exponent matrix

$$E ( {H}_{k} ) = ( {e}_{i , j}^{( k )} )$$

of m×n size, and each exponent is selected as one of {−1, 0, 1, 2, . . . , Lk−1} values.

The existing lifting method is configured with the same steps as C₀→C₁→ . . . →C_{S} and has a characteristic of satisfying a condition such as Lₖ₊₁=qₖ₊₁Lₖ (qₖ₊₁ is a positive integer, k=0, 1, . . . , S−1). In addition, if only the parity check matrix H_{S} of Cₛ is stored due to a characteristic of a lifting process, the QC-LDPC codes C₀, C₁, . . . , C_{S} may all be indicated using the following Equation 7 according to the lifting method.

$$E ( {H}_{k} ) ≡ ⌊ \frac{{L}_{k}}{{L}_{S}} E ( {H}_{S} ) ⌋ \qquad Equation 7$$

$$or$$

$$E ( {H}_{k} ) ≡ E ( {H}_{S} ) mod {L}_{k} \qquad Equation 8$$

Like this, a method of generating small codes Cᵢ (i=k−1, k−2, . . . 1, 0) from a large Cₖ code using an appropriate method such as Equation 7 or Equation 8, in addition to designing larger QC-LDPC codes C₁ . . . , C_{S}, and the like, from C₀, is called lifting.

In the lifting method of Equation 7 or Equation 8, Lis corresponding to a size of a row block or a column block in a parity check matrix of each QC-LDPC code Cₖ has a multiple relationship with each other, so that the exponent matrix is also selected by a specific method. This existing lifting method improves the algebraic or graph characteristics of each parity check matrix designed through lifting, making it easier to design a QC-LDPC code with an improved error floor characteristic.

In general, lifting may be used for LDPC encoding and decoding by changing values of entries for various L values in the exponent matrix of Equation 4.

For example, when the exponent matrix of Equation 4 is E=(a_{i,j}) and an exponent matrix converted according to the L values is

$${E}_{L} = ( {a}_{ij}^{( J )} ) ,$$

the following transformation equation such as Equation 9 may be applied in general.

$${a}_{i , j}^{( L )} = \{ \begin{matrix}{a}_{i , j} & {a}_{i , j} < 0 \\ f ( {a}_{i , j} , L ) & {a}_{i , j} \geq 0\end{matrix} \qquad Equation 9$$

$$or$$

$${a}_{i , j}^{( L )} = \{ \begin{matrix}{a}_{i , j} & {a}_{i , j} \leq 0 \\ f ( {a}_{i , j} , L ) & {a}_{i , j} > 0\end{matrix}$$

In Equation 9, f(x,L) may be defined in various forms. For example, definitions such as Equation 10 may be used for f(x,L).

$$f ( x , L ) = mod ( x , {2}^{⌊ {log}_{2} L ⌋} ) \qquad Equation 10$$

$$or$$

$$f ( x , L ) = ⌊ \frac{x}{{2}^{D - ⌊ {log}_{2} L ⌋}} ⌋$$

$$or$$

$$f ( x , L ) = ⌊ \frac{L}{D} x ⌋$$

In Equation 10, mod (a,b) means a modulo-b operation for a, and D means a constant that is a predefined positive integer.

For reference, in the conversion equation of Equation 9, a criterion for applying the conversion equation f is indicated as 0 for convenience, but a reference value may be set differently according to the block size L value to be supported. In addition, in a case that an exponent corresponding to the 0 matrix is excluded from the beginning in the representation of the exponent matrix or LDPC sequence, a rule for values with an exponent less than 0 in Equation 9 may be omitted.

As another embodiment of the disclosure, a case of applying LDPC encoding and decoding based on a plurality of exponent matrices or LDPC sequences on one basic matrix determined will be described. In other words, as the base matrix is fixed as one, determines the exponent matrix or sequence of the LDPC code defined on the base matrix, and applies lifting from the exponent matrix or sequence to a block size included in each block size group, performing variable length LDPC encoding and decoding may be performed. In this method, although the entries or numbers configuring the exponent matrix of the LDPC code or the LDPC sequence may have different values, positions of the corresponding elements or numbers exactly match on the base matrix. As such, the exponent matrix or the LDPC sequence refers to an exponent of the circulant permutation matrix, that is, a kind of circular shift value for bits, making it easy to identify positions of bits corresponding to the corresponding circular permutation matrix, by setting all the positions of entries or numbers the same. For reference, since the exponent matrix or the LDPC sequence corresponds to the circular shift value of bits corresponding to the block size Z, the exponent matrix may be variously named, such as a shift matrix, a shift value matrix, or a shift sequence, or a shift value sequence.

Divide the block size Z to be supported into a plurality of block size groups (or sets) as shown in Equation 11 below. Note that the block size Z is a value corresponding to a size Z×Z of the circulant permutation matrix or the circulant matrix in the parity check matrix of the LDPC code.

$$Z 1 = \{ 2 , 4 , 8 , 16 , 32 , 64 , 128 , 256 \} \qquad Equation 11$$

$$Z 2 = \{ 3 , 6 , 12 , 24 , 48 , 96 , 192 , 384 \}$$

$$Z 3 = \{ 5 , 10 , 20 , 40 , 80 , 160 , 320 \}$$

$$Z 4 = \{ 7 , 14 , 28 , 56 , 112 , 224 \}$$

$$Z 5 = \{ 0 , 18 , 36 , 72 , 144 , 288 \}$$

$$Z 6 = \{ 11 , 22 , 44 , 88 , 176 , 352 \}$$

$$Z 7 = \{ 13 , 26 , 52 , 104 , 208 \}$$

$$Z 8 = \{ 15 , 30 , 60 , 120 , 240 \}$$

Equation 11 is only an example, and embodiments may be expanded through various modifications. According to an embodiment of the disclosure, all block size Z values included in the block size group of Equation 11 may be used. In addition, according to an embodiment of the disclosure, a block size value included in an appropriate subset may be used as shown in Equation 12 below. In addition, according to an embodiment of the disclosure, appropriate values may be used by being added or excluded from the block size group (or set) of Equation 11 or Equation 12.

$$Z {1}^{′} = \{ 8 , 16 , 32 , 64 , 128 , 256 \} \qquad Equation 12$$

$$Z {2}^{′} = \{ 12 , 24 , 48 , 96 , 192 , 384 \}$$

$$Z {3}^{′} = \{ 10 , 20 , 40 , 80 , 160 , 320 \}$$

$$Z {4}^{′} = \{ 7 , 14 , 28 , 56 , 112 , 224 \}$$

$$Z {5}^{′} = \{ 18 , 36 , 72 , 144 , 288 \}$$

$$Z {6}^{′} = \{ 11 , 22 , 44 , 88 , 176 , 352 \}$$

$$Z {7}^{′} = \{ 26 , 52 , 104 , 208 \}$$

$$Z {8}^{′} = \{ 15 , 30 , 60 , 120 , 240 \}$$

The block size groups of Equation 11 and Equation 12 have a characteristic that a ratio of adjacent block sizes is all the same integers in addition to having different granularities. In other words, block sizes included in one group are in a divisor or multiple relationship with each other. When an exponent matrix corresponding to the p (p=1, 2, . . . , 8)-th group is

$${E}_{p} = ( {e}_{i , j}^{( p )} ) ,$$

and an exponent matrix corresponding to the Z value included in the p-th group is Eₚ(Z)=(e_{i,j}(Z)), apply the sequence conversion method shown in Equation 9 using fₚ(x,Z)=x(mod Z). For example, in a case that the block size Z is determined as Z=28, each entry e_{i,j}(28) of an exponent matrix (or an LDPC sequence) E₄(28)=(e_{i,j}(28)) for Z=28 may be obtained for an exponent matrix (or an LDPC sequence)

$${E}_{4} = ( {e}_{( i , j )}^{( 4 )} )$$

corresponding to a fourth block size group in which Z=28 is included as shown in Equation 13 below.

$${e}_{i , j} ( 28 ) = \{ \begin{matrix}{e}_{( i , j )}^{( 4 )} & {e}_{( i , j )}^{( 4 )} \leq 0 \\ {e}_{( i , j )}^{( 4 )} ( mod 28 ) & {e}_{( i , j )}^{( 4 )} > 0\end{matrix} \qquad Equation 13$$

$${or}^{′} ↵$$

$${e}_{i , j} ( 28 ) = \{ \begin{matrix}{e}_{( i , j )}^{( 4 )} & {e}_{( i , j )}^{( 4 )} < 0 \\ {e}_{( i , j )}^{( 4 )} ( mod 28 ) & {e}_{( i , j )}^{( 4 )} \geq 0\end{matrix}$$

The conversion shown in Equation 13 is simply indicated in Equation 14 below.

$${E}_{p} ( Z ) = {E}_{p} ( mod Z ) , Z ∈ {Z}_{p} \qquad Equation 14$$

For reference, the lifting or exponent matrix conversion method in Equations 9, 10, or Equations 11 to 14 is described by assuming to be applied to the entire exponent matrix corresponding to the parity check matrix, but this conversion method is also partially applicable to the exponent matrix.

In general, a submatrix corresponding to a parity bit of a parity check matrix often has a special structure for efficient encoding. In this case, the encoding method or complexity may be changed by lifting. Therefore, to maintain the same encoding method or complexity, lifting may not be applied to some of the exponent matrix for the submatrix corresponding to a parity in the parity check matrix, or a different lifting from the lifting method applied to the exponent matrix for the submatrix matrix corresponding to an information word bit may be applied. In other words, a lifting method applied to a sequence corresponding to the information word bit and a lifting method applied to a sequence corresponding to a parity bit may be set differently in the exponent matrix, and in some cases, a fixed value may be used without the sequence conversion since lifting is not applied to some or all of sequences corresponding to the parity bit.

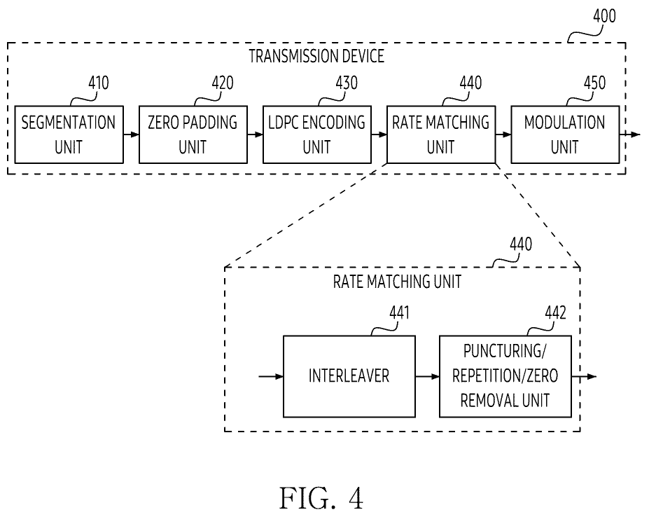

FIG. 4 is a block diagram of a transmission device according to an embodiment of the disclosure.

Referring to FIG. 4, a transmission device 400 may include a segmentation unit 410, a zero padding unit 420, an LDPC encoding unit 430, a rate matching unit 440, and a modulation unit 450 to process variable length input bits. The rate matching unit 440 may include an interleaver 441 and a puncturing/repetition/zero removal unit 442.

Herein, a component illustrated in FIG. 4 is a component that performs encoding and modulation on the variable length input bits, which is only an example, and in some cases, some of the components illustrated in FIG. 4 may be omitted or changed, and another component may be further added. As an example of a modulation method, any of methods of a QAM method such as a Quadrature Phase Shift Keying (QPSK), 16-Quadrature Amplitude Modulation (QAM), 64-QAM, 256-QAM, 1024-QAM, or a phase shift keying (PSK) or amplitude and PSK (APSK) method, and the like, are possible to use.

The transmission device 400 may determine a necessary parameter (e.g., an input bit length, a modulation and code rate (ModCod), a parameter for zero padding (or shortening), a code rate of an LDPC code, an information word or codeword length, a parameter for interleaving, a parameter for repetition and puncturing, and a modulation method, and the like), and encode an input bit based on the determined parameter, and transmit it to the reception device 500.

In terms of a fact that the number of input bits is variable, in a case that the number of input bits is greater than a preset value, the input bits may be segmented to have a length equal to or less than the preset value. In addition, each segmented block may correspond to one LDPC coded block. However, in a case that the number of input bits is less than or equal to the preset value, it is not segmented. The input bits may correspond to one LDPC coded block.

The transmission device 400 may pre-store various parameters used for encoding, interleaving, and modulation. Herein, a parameter used for encoding may include at least one of a code rate of an LDPC code, an input bit or an information word or codeword length, and information on a parity check matrix. In addition, a parameter used for interleaving may include information on an interleaving rule, and a parameter used for modulation may include information on a modulation method. In addition, information on puncturing may include a puncturing length. In addition, information on repetition may include a repetition length. Information on the parity check matrix may include an exponent value of a circulant matrix in a case that the parity matrix presented in the disclosure is used. Each component configuring the transmission device 400 may perform an operation using this parameter.

Meanwhile, functional components for channel encoding have been described in FIG. 4, but in some cases, the transmission device 400 may further include components (not illustrated) for controlling an operation of the transmission device 400.

According to an embodiment of the disclosure, the transmission device 400 may further include a communication unit. The communication unit performs functions for transmitting and receiving signals through a wireless channel. For example, the communication unit performs a conversion function between a baseband signal and a bit stream according to a physical layer specification of a system. For example, when transmitting data, the communication unit generates complex symbols by encoding and modulating a transmission bit stream. In addition, when receiving data, the communication unit restores a reception bit stream by demodulating and decoding a baseband signal. In addition, the communication unit up-converts the baseband signal into a radio frequency (RF) band signal and transmits it through an antenna, and then down-converts the RF band signal received through the antenna into the baseband signal. According to various embodiments of the disclosure, the transmission device 400 may transmit the LDPC-encoded signal to the reception device 500 to be described later.

To this end, the communication unit may include a transmission filter, a reception filter, an amplifier, a mixer, an oscillator, a digital to analog converter (DAC), an analog to digital converter (ADC), and the like. In addition, the communication unit may include a plurality of transmission/reception paths. Furthermore, the communication unit may include at least one antenna array configured with a plurality of antenna elements. In terms of hardware, the communication unit may be configured with a digital unit and an analog unit, and the analog unit may be configured with a plurality of sub-units according to operating power, operating frequency, and the like.

The communication unit may transmit and receive signals. To this end, the communication unit may include at least one transceiver. For example, the communication unit may transmit a synchronization signal, a reference signal, system information, a message, control information, or data, and the like. In addition, the communication unit may perform beamforming.

The communication unit transmits and receives signals as described above. Accordingly, all or part of the communication unit may be referred to as a ‘transmission unit’, a ‘reception unit’, or a ‘transmission/reception unit’. In addition, in the following description, transmission and reception performed through a wireless channel are used to include the processing performed by the communication unit as described above.

According to an embodiment of the disclosure, the transmission device 400 may further include a storage unit. The storage unit may store a basic program, an application program for an operation of the transmission device 400, data such as setting information, and the like, and the above-described parameters. The storage unit may include memory. The storage unit may be configured with volatile memory, non-volatile memory, or a combination of the volatile memory and the non-volatile memory. In addition, the storage unit may provide data stored according to a request of a control unit.

According to an embodiment of the disclosure, the transmission device 400 may further include a control unit. The control unit may control overall operations of the transmission device 400. For example, the control unit transmits and receives signals through the communication unit. In addition, the control unit records and reads data in the storage unit. In addition, the control unit may perform functions of a protocol stack required by a communication standard. To this end, the control unit may include at least one processor. The above-described operations for channel encoding, which is a stored instruction set or code, may be at least a temporarily resided instruction/code or a storage space in which the instruction/code is stored, or may be a portion of circuitry configuring the control unit. According to various embodiments of the disclosure, the control unit may control the transmission device to perform operations according to various embodiments described below.

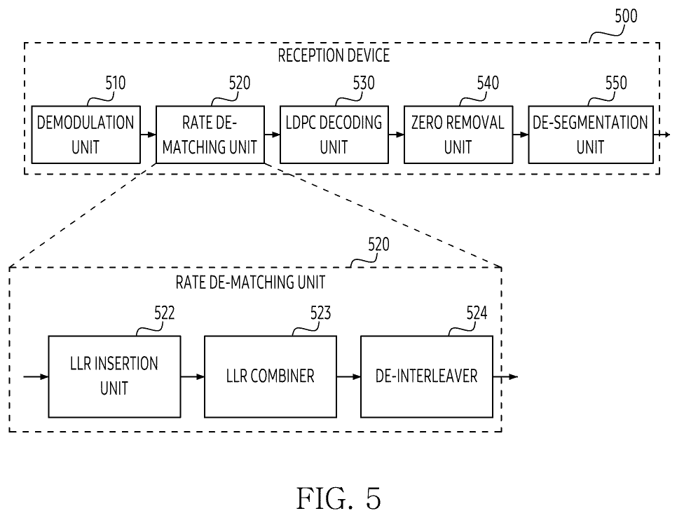

FIG. 5 is a block diagram of a reception device according to an embodiment of the disclosure.

Referring to FIG. 5, a reception device 500 may include a demodulation unit 510, a rate de-matching unit 520, an LDPC decoding unit 530, a zero removal unit 540, and a de-segmentation unit 550, and the like, to process variable length information. The rate de-matching unit 520 may include a log likelihood ratio (LLR) insertion unit 522, an LLR combiner 523, a de-interleaver 524, and the like. Names of the LLR insertion unit 522 and the LLR combiner 523, and the like, may vary according to values used for decoding. For example, in a case that decoding is performed based on values such as likelihood ratio (LR) instead of LLR, names may be determined based on values used for decoding, such as an LR insertion unit and an LR combiner, and the like, and an operation may vary slightly based on the values.

An operation of the demodulation unit 510 may be represented by being subdivided into several processes in some cases. For example, the demodulation unit 510 may be subdivided into a process of obtaining a channel estimation result based on a received signal and a process of determining values (e.g., LLR or LR, or a corresponding value) required for forward error control (FEC) decoding corresponding to a codeword bit transmitted from a demodulated signal or symbol based on the channel estimation result. In this case, an operation within each demodulation unit may be subdivided into each channel measurement block and a symbol-to-LLR conversion block, and the like. Of course, various subdivisions are possible according to a structure of the system.

Herein, a component illustrated in FIG. 5 is a component that performs a function corresponding to the component illustrated in FIG. 5, which is only an example, and in some cases, some may be omitted or changed, and another component may be added.

A parity check matrix in the disclosure may be read using memory, may be pre-given by a transmission device or a reception device, or may be generated directly by the transmission device or the reception device. In addition, the transmission device may store or generate a sequence, or an exponent matrix corresponding to the parity check matrix and apply it to encoding. Likewise, it is certain that the reception device also may store or generate a sequence, or an exponent matrix corresponding to the parity check matrix, and apply it to decoding.

Hereinafter, an operation of the reception device will be described based on FIG. 5. The demodulation unit 510 demodulates a signal received from a transmission device 400. Specifically, the demodulation unit 510, which is a component corresponding to a modulation unit 450 of the transmission device 400, may generate a value (e.g., LLR, LR, or a corresponding value) corresponding to bits transmitted from the transmission device 400 by receiving and demodulating the signal transmitted from the transmission device 400. To this end, the reception device 500 may pre-store information on a modulation method modulated according to a mode in the transmission device 400. Accordingly, the demodulation unit 510 may generate values corresponding to the LDPC codeword bits by demodulating the signal received from the transmission device 400 according to the mode.

An LR value means a ratio of a probability that a bit transmitted from the transmission device 400 is 0 to a probability that the bit transmitted from the transmission device 400 is 1, and an LLR value may be indicated as a value obtained by taking Log to the ratio of the probability that the bit transmitted from the transmission device 400 is 0 and 1. Alternatively, the LR or LLR value may be indicated as a bit value itself by being hard decided according to the probability or the ratio of the probability or the an Log value for the ratio of the probability, or may be indicated as a predefined representative value according to a section in which the probability or the ratio of the probability or the Log value for the ratio of the probability belongs. An example of a method of determining the predefined representative value according to the section in which the probability or the ratio of the probability or the Log value for the ratio of the probability belongs is a method considering quantization, and the like. In addition, various other values corresponding to the probability or the ratio of the probability or the Log value for the ratio of the probability may be used.

In the disclosure, a reception method and operations of a device are described by exemplifying an LLR value as a probability value for determination for convenience, but it is not necessarily limited thereto.

The demodulation unit 510 includes a function of performing multiplexing (not illustrated) for the LLR value. Specifically, a mux (not illustrated) is a component corresponding to a bit de-mux (not illustrated) of the transmission device 400, and may perform an operation corresponding to the bit de-mux (not illustrated). To this end, the reception device 500 may have pre-stored information on a parameter used by the transmission device 400 for demultiplexing and block interleaving. Accordingly, the mux (not illustrated) may inversely perform demultiplexing and block interleaving operations performed in the bit de-mux (not illustrated) for an LLR value corresponding to a cell word (information indicating a reception symbol for an LDPC codeword as a vector value), thereby multiplexing the LLR value corresponding to the cell word in bit units.

The rate de-matching unit 520 may additionally insert an LLR value into LLR values outputted from the demodulation unit 510. In this case, the rate de-matching unit 520 may insert predetermined LLR values between the LLR values outputted from the demodulation unit 510. Specifically, the rate de-matching unit 520 is a component corresponding to a rate matching unit 440 of the transmission device 400, and may perform an operation corresponding to an interleaver 441, a zero removal, and puncturing/repetition/zero removal unit 442.

The rate de-matching unit 520 performs deinterleaving to correspond to the interleaver 441 of the transmitter. An LLR value corresponding to zero bits may be inserted into the output values of the de-interleaver 524 at a position where the zero bits have been padded in the LDPC codeword in the LLR insertion unit 522. In this case, the LLR value corresponding to the padded zero bits, that is, the shorted zero bits may be ∞ or −∞. However, ∞ or −∞ is a theoretical value, and may substantially be a maximum or minimum value of the LLR value used in the reception device 500.

To this end, the reception device 500 may have pre-stored information on a parameter used by the transmission device 400 to pad the zero bits. Accordingly, the rate de-matching unit 520 may determine a position where the zero bits have been padded in the LDPC codeword, and insert an LLR value corresponding to the zero bits shorted at a corresponding position.

In addition, the LLR insertion unit 522 of the rate de-matching unit 520 may insert an LLR value corresponding to the punctured bits at a position of the punctured bits in the LDPC codeword. In this case, the LLR value corresponding to the punctured bits may be 0 or another pre-determined value. In general, in a case that parity bits with a degree of 1 are punctured, since they have no effect on improving performance in the LDPC decoding process, they may not be used in an LDPC decoding process without inserting LLR into some or all of a corresponding puncturing position. However, in order to increase efficiency of the LDPC decoding process based on parallel processing, the LLR insertion unit 522 may insert a predetermined LLR value at a position corresponding to some or all of the puncturing bits with a degree of 1 regardless of the improvement in decoding performance. To this end, the reception device 500 may pre-store information on a parameter used for puncturing in the transmission device 400. Accordingly, the LLR insertion unit 522 may insert an LLR value (e.g., LLR=0) corresponding to a position where LDPC information word bits or parity bits are punctured. However, this process may be omitted at a position of some punctured parity bits.

The LLR combiner 523 may combine, that is, add up an LLR value outputted from the LLR insertion unit 522 and the demodulation unit 510. Specifically, the LLR combiner 523 is a component corresponding to the puncturing/repetition/zero removal unit 442 of the transmission device 400, and may perform an operation corresponding to the repetition unit 442. First, the LLR combiner 523 may combine an LLR value corresponding to repeated bits with another LLR value. Herein, the other LLR value may be an LLR value for bits which becomes the basis for generation of the repeated bits in the transmission device 400, that is, may be an LLR value for LDPC information word bits or parity bits selected as a target of the repetition. Additionally, according to TS 38.212 document, which is a third generation partnership project (3GPP) fifth generation (5G) standard, the repeated bits may be determined in various ways based on a parameter such as a redundancy version (RV) value or a code rate, which are set during a retransmission process, such as a hybrid automatic repeat request (ARQ) (HARQ).

As described above, the transmission device 400 selects LDPC encoding bits, repeats some of the LDPC information word bits and LDPC parity bits if necessary, and transmits them to the reception device 500. Accordingly, the LLR value for the LDPC encoding bits may configured with an LLR value for the repeated LDPC encoding bits and an LLR value for the non-repeated LDPC encoding bits. The LLR combiner 523 may combine LLR values corresponding to the same LDPC encoding bits. To this end, the reception device 500 may pre-store information on a parameter used for repetition in the transmission device 400. Accordingly, the LLR combiner 523 may determine the LLR value for the repeated LDPC encoding bits and combine it with the LLR value for the LDPC encoding bits on which the repetition is based.

In addition, the LLR combiner 523 may combine an LLR value corresponding to retransmission or increment redundancy (IR) bits with another LLR value. Herein, the other LLR value may be an LLR value for some or all of the LDPC codeword bits based on generation of retransmission or increment redundancy (IR) bits in the transmission device 400.

As described above, in a case that negative acknowledgment (NACK) occurs for HARQ, the transmission device 400 may transmit some or all of the codeword bits to the reception device 500. Accordingly, the LLR combiner 523 may combine LLR values for bits received through a retransmission or IR with LLR values for LDPC codeword bits received through a previous frame. To this end, the reception device 500 may pre-store information on a parameter used for generation of a retransmission or of IR bit in the transmission device 400. Accordingly, the LLR combiner 523 may determine the LLR value for the retransmission or IR bit and combine it with the LLR value for at least some of the LDPC encoding bits which becomes the basis of the generation of the retransmission bits.

The de-interleaver 524 may deinterleave the LLR value outputted from the LLR combiner 523. Specifically, the de-interleaver 524 is a component corresponding to the interleaver 441 of the transmission device 400, and may perform an operation corresponding to the interleaver 441. To this end, the reception device 500 may have pre-stored information on a parameter used by the transmission device 400 for interleaving. Accordingly, the de-interleaver 524 may inversely perform the interleaving operation performed by the interleaver 441 on an LLR value corresponding to the transmitted LDPC encoding bits to deinterleave the LLR value corresponding to the transmitted LDPC encoding bits.

The LDPC decoding unit 530 may perform LDPC decoding based on the LLR value outputted from the rate de-matching unit 520. Specifically, the LDPC decoding unit 530 is a component corresponding to an LDPC encoding unit 430 of the transmission device 400, and may perform an operation corresponding to the LDPC encoding unit 430. To this end, the reception device 500 may have pre-stored information on a parameter used in the transmission device 400 to perform LDPC encoding according to a mode. Accordingly, the LDPC decoding unit 530 may perform LDPC decoding based on the LLR value outputted from the rate de-matching unit 520 according to the mode. For example, the LDPC decoding unit 530 may perform LDPC decoding based on the LLR value outputted from the rate de-matching unit 520 based on an iterative decoding method based on a sum-product algorithm, and output bits corrected for errors according to the LDPC decoding.

The zero removal unit 540 may remove zero bits from the bits outputted from the LDPC decoding unit 530. Specifically, the zero removal unit 540 is a component corresponding to a zero padding unit 420 of the transmission device 400, and may perform an operation corresponding to the zero padding unit 420. To this end, the reception device 500 may have pre-stored information on a parameter used to pad the zero bits in the transmission device 400. Accordingly, in a case that the LDPC decoding unit 530 performs decoding using the padded bits, the zero removal unit 540 may remove the zero bits padded in the zero padding unit 420 from the outputted bits. The operation of removing the zero-padded (or shortened) bits in the zero-removal unit 540 may mean an operation of actually removing the padding bits, but may mean, when transmitting the outputted bits of the LDPC decoding unit 530 to the next de-segmentation unit 550, an operation of excluding the padded bits and transmitting them. Additionally, the zero-padded bits in the transmitting device may not be used in the decoding process since the reception device knows their position exactly, and in this case, the process of removing the zero-padded bits may be omitted.

The de-segmentation unit 550 is a component corresponding to a segmentation unit 410 of the transmission device 400, and may perform an operation corresponding to the segmentation unit 410. To this end, the reception device 500 may have pre-stored information on a parameter used by the transmission device 400 for segmentation. Accordingly, the de-segmentation unit 550 may restore bits before the segmentation by combining bits outputted from the zero removal unit 540, that is, segments for variable length input bits.

According to an embodiment of the disclosure, the LDPC code may be decoded using an iterative decoding algorithm based on the sum-product algorithm on the dichotomy graph listed in FIG. 2, and the sum-product algorithm is a type of message passing algorithm.

Meanwhile, in FIG. 5, functional components for channel decoding have been described, but in some cases, the reception device 500 may further include components (not illustrated) for controlling the operation of the reception device 500.

According to an embodiment of the disclosure, the reception device 500 may further include a communication unit. The communication unit performs functions for transmitting and receiving signals through a wireless channel. For example, the communication unit performs a conversion function between a baseband signal and a bit stream according to a physical layer specification of a system. For example, when transmitting data, the communication unit generates complex symbols by encoding and modulating a transmission bit stream. Furthermore, when receiving data, the communication unit restores a reception bit stream by demodulating and decoding a baseband signal. In addition, the communication unit up-converts the baseband signal into a radio frequency (RF) band signal and transmits it through an antenna, and then down-converts the RF band signal received through the antenna into the baseband signal. According to various embodiments of the disclosure, the reception device 500 may receive an LDPC-encoded signal from the transmission device 400.

To this end, the communication unit may include a transmission filter, a reception filter, an amplifier, a mixer, an oscillator, a digital to analog converter (DAC), an analog to digital converter (ADC), and the like. In addition, the communication unit may include a plurality of transmission/reception paths. Furthermore, the communication unit may include at least one antenna array configured with a plurality of antenna elements. In terms of hardware, the communication unit may be configured with a digital unit and an analog unit, and the analog unit may be configured with a plurality of sub-units according to operating power, operating frequency, and the like.

The communication unit may transmit and receive signals. To this end, the communication unit may include at least one transceiver. For example, the communication unit may transmit a synchronization signal, a reference signal, system information, a message, control information, or data, and the like. In addition, the communication unit may perform beamforming.

The communication unit transmits and receives signals as described above. Accordingly, all or part of the communication unit may be referred to as a ‘transmission unit’, a ‘reception unit’, or a ‘transmission/reception unit’. In addition, in the following description, transmission and reception performed through a wireless channel are used to include the processing performed by the communication unit as described above.

According to an embodiment of the disclosure, the transmission device 400 may further include a storage unit. The storage unit may store a basic program, an application program for an operation of the transmission device 400, data such as setting information, and the like, and the above-described parameters. The storage unit may include memory. The storage unit may be configured with volatile memory, non-volatile memory, or a combination of the volatile memory and the non-volatile memory. In addition, the storage unit may provide data stored according to a request of a control unit.

According to an embodiment of the disclosure, the transmission device 400 may further include a control unit. The control unit may control overall operations of the transmission device 400. For example, the control unit transmits and receives signals through the communication unit. In addition, the control unit records and reads data in the storage unit. In addition, the control unit may perform functions of a protocol stack required by a communication standard. To this end, the control unit may include at least one processor. The above-described operations for channel encoding, which is a stored instruction set or code, may be at least a temporarily resided instruction/code or a storage space in which the instruction/code is stored, or may be a portion of circuitry configuring the control unit. According to various embodiments of the disclosure, the control unit may control the transmission device to perform operations according to various embodiments described below.

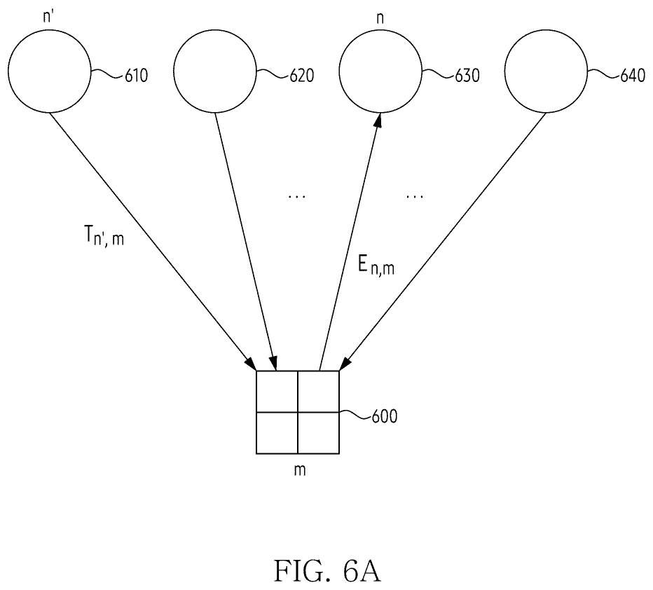

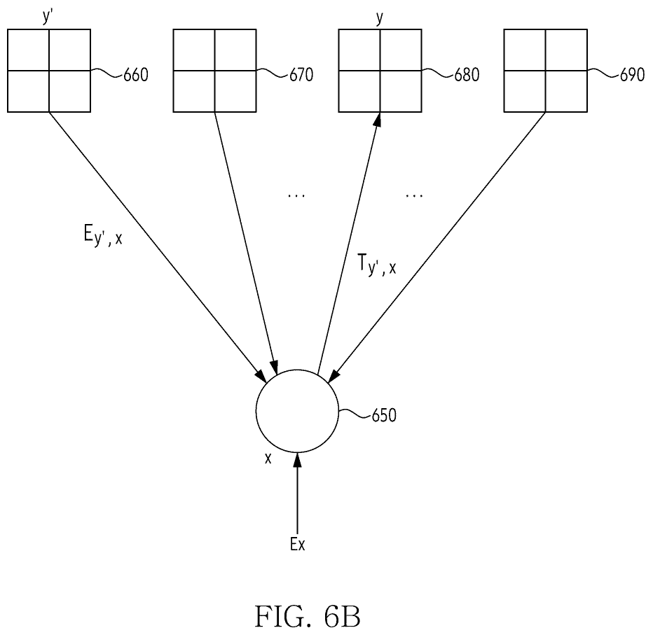

FIGS. 6A and 6B are message structure diagrams indicating a message passing operation at an arbitrary check node and a variable node for LDPC decoding according to various embodiments of the disclosure.

Hereinafter, a message passing operation generally used in LDPC decoding will be described with reference to FIGS. 6A and 6B.

FIGS. 6A and 6B are diagrams illustrating the message passing operation at the arbitrary check node and the variable node for LDPC decoding. The message passing operation may include an update operation of the check node and an update operation of the variable node. An update process of a variable node n is described in FIG. 6A, and an update process of a check node y is described in FIG. 6B.

Referring to FIG. 6A, a plurality of variable nodes 610, 620, 630, and 640 connected to a check node m 600 are illustrated. In addition, an illustrated Tn′,m indicates a message that is passed from the variable node n′ 610 to the check node m 600, and En,m indicates a message that is passed from the check node m 600 to the variable node n 630. Herein, a set of all variable nodes connected to the check node m 600 is represented as N(m), and a set excluding the variable node n 630 in N(m) is represented as N(m)\n.

In this case, a message update rule based on a sum-product algorithm may be indicated as Equation 15 below.

$$\vert {E}_{n , m} \vert = Φ [ {\sum }_{{n}^{′} ∈ N ( m ) \backslash n} Φ ( \vert {T}_{{n}^{′} , m} \vert ) ] \qquad Equation 15$$

$$Sign ( {E}_{n , m} ) = {\prod }_{{n}^{′} ∈ N ( m ) \backslash n} sign ( {T}_{{n}^{′} , m} )$$

Herein, Sign(E_{n,m}) indicates a sign of the message E_{n,m}, and |E_{n,m}| indicates magnitude of the message E_{n,m}. Meanwhile, a function Φ(x) may be indicated as Equation 16 below.

$$Φ ( x ) = - log ( tanh ( \frac{x}{2} ) ) \qquad Equation 16$$

For reference, the −log(tanh(.)) function of Equation 16 may be more simply represented as a log(coth(.)) function.

Referring to FIG. 6B, a plurality of check nodes 660, 670, 680, and 690 connected to a variable node x 650 are illustrated. In addition, an illustrated E_{y′,x} indicates a message that is passed from the check node y′ 660 to the variable node x 650, and T_{y,x} indicates a message that is passed from the variable node x 650 to the check node y 680. Herein, a set of all check nodes connected to the variable node x 650 is represented as M(x), and a set excluding the check node y 680 in M(x) is represented as M(x)\y. In this case, a message update rule based on the sum-product algorithm may be indicated as Equation 17 below.

$${T}_{y , x} = {E}_{x} + {\sum }_{{y}^{′} ∈ M ( x ) \backslash y} {E}_{{y}^{′} , x} \qquad Equation 17$$

Herein, Eₓ refers to an initial message value of the variable node x.

In addition, in a case of determining a bit value of the node x, it may be indicated as Equation 18 below.

$${P}_{x} = {E}_{x} + {\sum }_{{y}^{′} ∈ M ( x )} {E}_{{y}^{′} , x} . \qquad Equation 18$$

In this case, an encoding bit corresponding to the variable node x may be determined according to a Px value.

Since the above-described method in FIGS. 6A and 6B is a general decoding method, a detailed description thereof will be omitted. However, in addition to the method described in FIGS. 6A and 6B, another method may be applied to determine a value of the message passed at the variable node and the check node and for a detailed description of this, refer to ┌Frank R. Kschischang, Brendan J. Frey, and Hans-Andrea Loeliger, “Factor Graphs and the Sum-Product Algorithm,” IEEE TRANSACTIONS ON INFORMATION THEORY, VOL. 47, NO. 2, February 2001, pp498-519)┘. For example, in Equation 15 and Equation 16, the update equation of the check node was indicated in a form of a sum by representing it based on the −log(tanh(.) function, but in the reference literature, it was indicated in a form of a product based on the tanh(.) function or its inverse function tanh⁻¹(.). As such, there may be various representation methods that are conceptually the same. In addition, various simplified decoding methods such as a min-sum algorithm may exist to reduce complexity. Although detailed descriptions of these various decoding algorithms are omitted in the disclosure, it is obvious that a decoding scheduling method to be proposed in the disclosure and various other types of decoding algorithms as well as the above decoding algorithms may be combined.

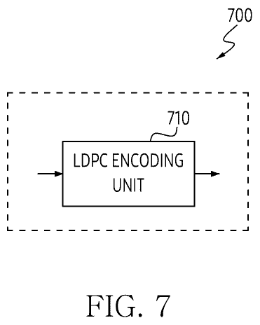

FIG. 7 is a block diagram illustrating a configuration of an LDPC encoding unit according to an embodiment of the disclosure.

K_{ldpc} bits may configure K_{ldpc} information word bits I=(i₀, i₁, . . . , i_{K}_{_{ldpc}}₋₁) for an LDPC encoding unit 700. The LDPC encoding unit 700 may generate an LDPC codeword C=(c₀,c₁, . . . , c_{Nldpc-1})=(i₀,i₁, . . . , i_{Kldpc-1},p₀,p₁, . . . ,P_{Nldpc-Kldpc-1}) configured with N_{ldpc} bits by systemically encoding the K_{ldpc} information word bits. As described in

Equation 1 above, a codeword is determined so that a product of the LDPC codeword and a parity check matrix becomes a zero vector.

Referring to FIG. 7, an encoding unit 700 includes an LDPC encoding unit 710. The LDPC encoding unit 710 may generate an LDPC codeword by performing LDPC encoding on input bits, based on a parity check matrix, or an exponent matrix or a sequence corresponding thereto. In this case, the LDPC encoding unit 710 may perform LDPC encoding using a parity check matrix defined differently according to a code rate (i.e., a code rate of an LDPC code) or a length of an input bit (or a codeword or an information word) or a block length Z.

Meanwhile, the encoding unit 700 may further include memory (not illustrated) for pre-storing information on the code rate of the LDPC code, the length of the input bit (or the information word or the codeword), and the parity check matrix, and the LDPC encoding unit 710 may perform LDPC encoding using this information. The information on the parity check matrix may include information on an exponent value of a circulant matrix in a case of using the parity matrix presented in the disclosure.

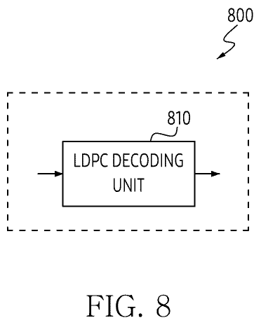

FIG. 8 is a block diagram illustrating a configuration of a decoding device according to an embodiment of the disclosure.

Referring to FIG. 8, a decoding device 800 may include an LDPC decoding unit 810. The LDPC decoding unit 810 performs LDPC decoding on an LDPC codeword based on a parity check matrix, or an exponent matrix or a sequence corresponding thereto. For example, the LDPC decoding unit 810 may generate information word bits by performing LDPC decoding by passing an LLR value corresponding to LDPC codeword bits through an iterative decoding algorithm. Herein, the LLR value is a channel value corresponding to the LDPC codeword bits transmitted from a transmitter, and may be represented in various ways.

According to an embodiment of the disclosure, the LDPC decoding unit 810 may perform LDPC decoding using a parity check matrix differently defined according to a code rate (i.e., a code rate of an LDPC code).

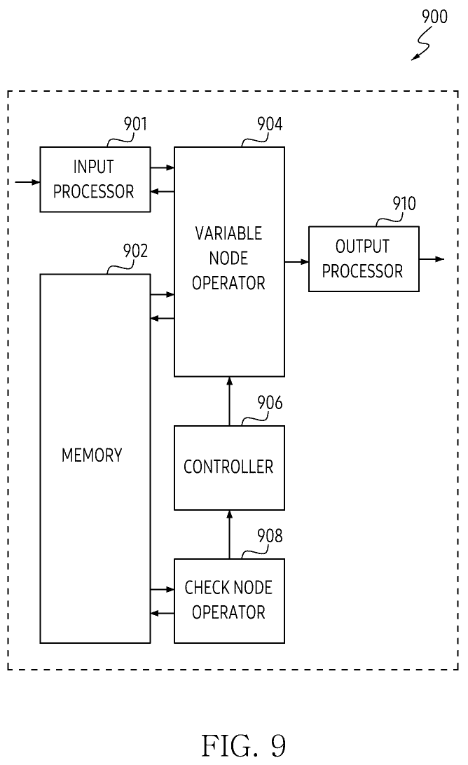

FIG. 9 indicates a functional configuration of an LDPC decoding unit according to an embodiment of the disclosure.

As described above, an LDPC decoding unit 810 may perform LDPC decoding using an iterative decoding algorithm, and in this case, the LDPC decoding unit 810 may be configured in a structure as illustrated in FIG. 9. However, a configuration illustrated in FIG. 9 is also only an example.

Referring to FIG. 9, a decoding device 900 may include an input processor 901, memory 902, a variable node operator 904, a controller 906, a check node operator 908, an output processor 910, and the like.

The input processor 901 stores a value that is inputted. Specifically, the input processor 901 may store an LLR value of a reception signal received through a wireless channel.

The controller 906 determines a block size (i.e., a length of a codeword) of the reception signal received through the wireless channel, the number of values inputted to the variable node operator 904, an address value in the memory 902, the number of values inputted to the check node operator 908, an address value in the memory 902, and the like, based on a parity check matrix corresponding to a code rate.

The memory 902 stores input data and output data of the variable node operator 904 and the check node operator 908.

The variable node operator 904 receives data from the memory 902 according to address information of input data and information on the number of the input data received from the controller 906, and performs a variable node operation. Thereafter, the variable node operator 904 stores variable node operation results in the memory 902 based on address information of output data and information of the number of the output data received from the controller 906. In addition, the variable node operator 904 inputs the variable node operation result to the output processor 910 based on the data received from the input processor 901 and the memory 902. Herein, the variable node operation has been described above based on FIG. 6A.

The check node operator 908 receives data from the memory 902 based on the address information of the input data and the number of the input data received from the controller 906 and performs a check node operation. Thereafter, the check node operator 908 stores check node operation results in the memory 902 based on the address information of the output data and the number of the output data received from the controller 906. Herein, the check node operation has been described above based on FIG. 6B.

The output processor 910 performs a hard decision whether the information word bits of the codeword of a transmission side are 0 or 1 based on the data received from the variable node operator 904, and then outputs a hard decision result, and an output value of the output processor 910 becomes the finally decoded value. In this case, through FIGS. 6A and 6B, it may be hard-decided based on a value obtained by adding all message values (an initial message value and all message values inputted from the check node) inputted to one variable node.

Meanwhile, the memory 902 of the decoding device 900 may pre-store information on the code rate of the LDPC code, the length of the input bit (or the information word or the codeword), and the parity check matrix, and the LDPC decoder unit 810 may perform LDPC encoding using this information. However, this is only an example, and the information may be provided from the transmission side.

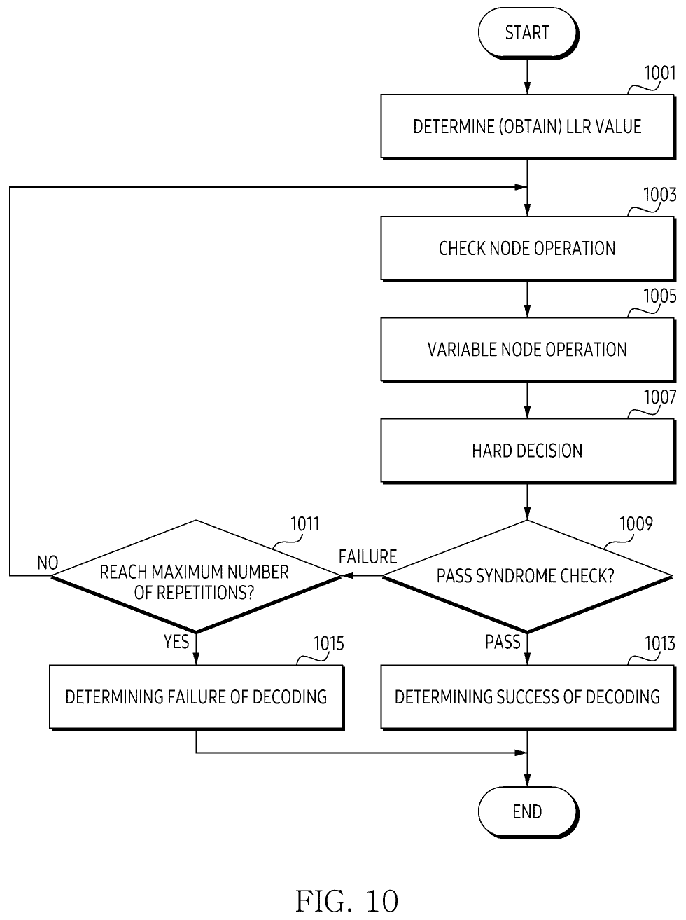

FIG. 10 illustrates an operation flow for LDPC decoding of an LDPC decoding device according to an embodiment of the disclosure.

The LDPC decoding device may be a reception device for receiving a signal encoded to an LDPC. For example, the LDPC decoding device may be a base station for decoding an uplink signal. In addition, for example, the LDPC decoding device may be a terminal for decoding a downlink signal.

Referring to FIG. 10, in operation 1001, the LDPC decoding device may obtain an LLR value. In each variable node, a value referred to as a channel LLR or an intrinsic LLR of a corresponding bit, generated from a reception signal may be inputted. The inputted LLR values may be rate de-matched LLR values.

According to an embodiment of the disclosure, the LDPC decoding device may perform LDPC decoding based on a flooding method. In LDPC decoding of the flooding method, all check nodes calculate and update a message value, and a message corresponding to a calculated extrinsic LLR is transmitted to a neighboring variable node along a connected connection line.

In operation 1003, the LDPC decoding device may perform a check node operation. An intrinsic LLR of each variable node is transmitted to a neighboring check node, and the LDPC decoding device calculates a message corresponding to an extrinsic LLR to be transmitted to each variable node at each of all check nodes based on the received message.

In operation 1005, the LDPC decoding device may perform a variable node operation. The LDPC decoding device generates a complete LLR for determining a message and a bit value to be transmitted to the check nodes at each of all variable nodes based on a message corresponding to the received extrinsic LLR, and intrinsic LLR values. The complete LLR may be referred to as a posteriori probability (APP) metric, an APP LLR, or another term having a technical meaning equivalent thereto. According to an embodiment of the disclosure, in the LDPC decoding device of the floating method, all variable nodes calculate and update a message value.

In operation 1007, the LDPC decoding device may perform a hard decision. The LDPC decoding device may estimate a bit value by hard-deciding the complete LLR at each variable node before transmitting a message from the variable node to the check node.

In operation 1009, the LDPC decoding device may determine whether the estimated bit value(s) pass a syndrome check. The syndrome check means a procedure for checking whether each row of a matrix obtained through a product of a channel matrix, and a transpose channel matrix of the estimated codeword obtained through operation 1007 is 0. In the LDPC decoding device, whether a syndrome check equation determined by the parity check matrix determined by the bit value estimated in operation 1007 is satisfied is checked. The syndrome check may be represented by Equation 19 to be described later.

In a case that it is confirmed that the syndrome check equation is satisfied, the LDPC decoding device may perform operation 1013. In operation 1013, the LDPC decoding device may determine that decoding has succeeded. It is determined that decoding of the received signal is successful, and the success of decoding is outputted and reported.

In a case that it is confirmed that the syndrome check equation is not satisfied, the LDPC decoding device may perform operation 1011. In operation 1011, the LDPC decoding device may determine whether to reach the maximum number of repetitions. In other words, it may be confirmed whether the number of iterative decodings performed so far has reached the maximum number of iterative decodings that is previously designated. In a case that the number of iterative decodings performed so far has not reached the maximum number of iterative decodings, the LDPC decoding device may re-perform the series of processes (e.g., operations 1003 to 1009). In a case that a decoding result does not satisfy the syndrome check equation until the number of iterative decodings performed so far reaches the maximum number of iterative decodings, the LDPC decoding device may perform operation 1015. In operation 1015, in the LDPC decoding device, a decoding failure is outputted and reported.

According to an embodiment of the disclosure, the LDPC decoding device may perform LDPC decoding of a layered method. Decoding of the layered method refers to a method of dividing check nodes into a plurality of layers and then sequentially performing decoding from the ordered check node.

Referring to FIG. 10, in operation 1003, the LDPC decoding device may perform the check node operation. The LDPC decoding device receives, at a check node belonging to the ordered layer, a message from a variable node connected to the corresponding check node. The LDPC decoding device transmits a message calculated and updated at the check node to a neighboring variable node.

In operation 1005, the LDPC decoding device may perform the variable node operation. In the LDPC decoding device, variable nodes that have received the updated message calculates and updates a message to be transmitted to the check node and the complete LLR. A series of operation processes for one layer as described above is referred to as layer processing. When the layer processing is performed on all layers, the LDPC decoding device may perform operation 1007.

In operation 1007, the LDPC decoding device may perform the hard decision. The LDPC decoding device calculates a bit estimation value by hard-deciding the complete LLR calculated at each variable node.

In operation 1009, the LDPC decoding device may determine whether the estimated bit value(s) pass the syndrome check. The LDPC decoding device checks whether decoding is successful or failed by performing the syndrome check based on the bit estimation value. In this case, check nodes of a parity check matrix corresponding to the syndrome check may be all check nodes or some predetermined check nodes. (For example, some or all of the check nodes connected to a variable node with a degree of 1 may be excluded.)

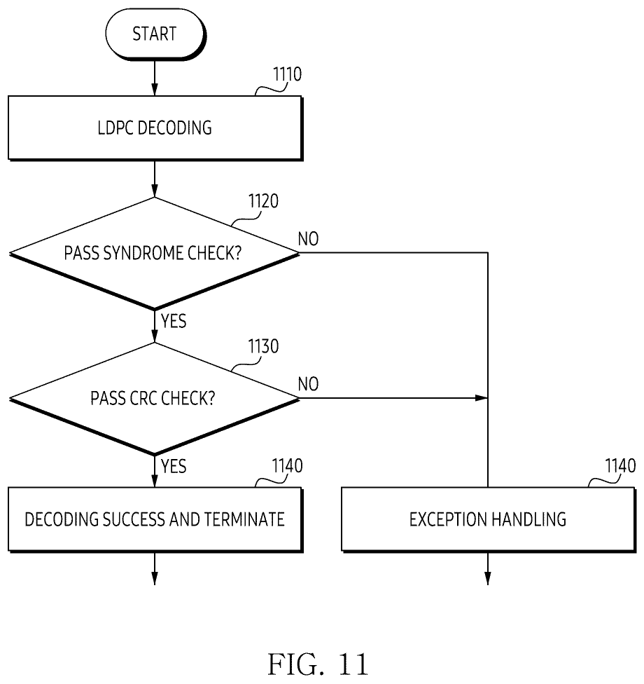

In general, an LDPC code may detect an error through a syndrome, but a CRC code may be additionally applied as an external code to support a higher level of an error detection capability. A general example of FEC decoding operation in a case that the CRC code as an external code and the LDPC code as an internal code are applied is described with reference to FIG. 11.

FIG. 11 illustrates an operation flow for decoding based on an LDPC and CRC code of an LDPC decoding device according to an embodiment of the disclosure.

The LDPC decoding device may be a reception device for receiving a signal encoded to an LDPC. For example, the LDPC decoding device may be a base station for decoding an uplink signal. In addition, for example, the LDPC decoding device may be a terminal for decoding a downlink signal.

Referring to FIG. 11, in operation 1110, the LDPC decoding device may perform LDPC decoding. In general, as illustrated in FIG. 11, the LDPC decoding device may perform step 1120 after performing LDPC decoding.

In operation 1120, the LDPC decoding device may determine whether to pass a syndrome check. The LDPC decoding apparatus determines whether to detect an error by identifying or checking a syndrome of an LDPC obtained through a decoding result. Herein, the LDPC syndrome means a value determined as shown in Equation 19 below when a codeword obtained through a hard decision after performing LDPC decoding is ĉ and a parity check matrix used for decoding is H.

$$s = H \cdot {\hat{c}}^{T} \qquad Equation 19$$

If a codeword transmitted from an actual transmitter is c, since H·c^{T}=0 is established by Equation 1, in a case that decoding is successfully performed, the syndrome s value of Equation 19 should also be 0. (In some cases, a case that the LDPC syndrome value is 0, it may be represented as passing by checking the LDPC syndrome value.) However, if the syndrome value is not 0 (or if the LDPC syndrome value has not passed), it means that c≠ĉ.

In a case of passing the syndrome check, the LDPC decoding device may perform operation 1130. In a case of not passing the syndrome check, the LDPC decoding device may perform operation 1150. In other words, in a case that the LDPC syndrome s value is not 0, the LDPC decoding device may perform operation 1150. The LDPC decoding device may determine, at a higher layer of a system, whether to use an information word bit or a code block that has performed LDPC decoding in operation 1150 by performing exception handling, or may determine whether to discard the information word bit or the code block that has performed the LDPC decoding as predetermined.

On the other hand, according to another embodiment of the disclosure, unlike as illustrated in FIG. 11, the LDPC decoding device may perform operation 1130 without performing exception handling directly in operation 1150 even when the LDPC syndrome s value is not 0 in operation 1120. In operation 1130, the LDPC decoding device may determine whether a CRC check is passed. The LDPC decoding device may perform CRC detection (or confirmation) on the information word bit. The reason is that, according to the LDPC decoding result, although codeword decoding has failed, there is a probability that, after the LDPC decoding, an error remain only in a parity bit and no error exist in the information word bit, and thus, the LDPC decoding device may perform CRC detection in operation 1130 to determine whether an error is detected in the information word bit.

In addition, as described above, in a case that the LDPC syndrome value according to LDPC decoding is 0, the LDPC decoding device may perform CRC detection in operation 1130. If it is determined that an information word bit vector has been successfully decoded through CRC detection in operation 1130, the LDPD decoding device may perform operation 1140. In operation 1140, the LDPC decoding device may determine a decoding success and terminate a decoding procedure. If, in operation 1130, it is determined from the CRC detection result that an error is included in the information word bit vector, the LDPC decoding device may perform exception handling on the decoded information word bit vector or the code block as in operation 1150, and may determine whether to use or not use the corresponding information word bit vector or code block at the higher layer of the system, or may determine whether to discard it.

It is noted that, in the disclosure, a meaning of exception handling may refer to all operations performed when decoding has failed or is determined to be likely to fail, in addition to operations that are to be performed when decoding has been successfully performed in all processes.

In addition, a receiver may generate an instruction or a flag with respect to whether decoding is successful and deliver them to a higher layer. In the higher layer, a method of processing information word bits or code blocks in which decoding is completed may be determined based on the instruction or the flag. (e.g., a decision of a retransmission request, and the like)

For reference, in Equation 19, it is c≠ĉ. but in a case that the decoded codeword ĉ is a codeword different from c, the LDPC syndrome may be 0. Since this error cannot be detected through the LDPC code (undetected error), the error may be detected only when performing CRC detection is performed after LDPC decoding.

Additionally, the syndrome value s may be obtained (or calculated or determined) through a calculation process based on the parity check matrix and the decoded codeword, as shown in Equation 19, but it may also be easily obtained according to an implementation characteristic of the LDPC decoder. For example, in Equation 15, the messages used in the decoding process for LDPC decoding may be decoded by dividing them into a size and a code, at this time, the syndrome value s may be easily obtained (or calculated or determined) through an operation of + or − signs of the messages. For example, in an actual implementation of the decoder, the LDPC decoding device may easily obtain the syndrome value based on an appropriate XOR operation by corresponding the + sign to 0 and the − sign to 1 as a binary number. More particularly, it is easy to identify whether or not the syndrome value is 0 from the implementation characteristic during an LDPC iterative decoding process. For reference, a hard decision of an actually LDPC-decoded codeword may also be easily determined based on signs of messages for each bit on which the LDPC decoding has been performed.

When checking or identifying the LDPC syndrome in operation 1120, in some embodiments of the disclosure, the LDPC decoding device does not necessarily need to check or identify all syndromes of the LDPC code, and may only check or identify some syndrome values. For example, syndrome values related to the check node connected to the variable node with a degree of 1, that is, a check node corresponding to the parity bit with a degree of 1, may not be used to check or identify in operation 1120. This is because bits corresponding to the variable node with a degree of 1 are usually significantly less likely to be corrected for an error, so even if the LDPC syndrome is checked, it is highly likely that the error has always been detected. As a result, the LDPC decoding device may check or identify the LDPC syndrome for all or some of the check node connected only to a variable node or a bit with a degree of 2 or higher in many cases to prevent an erroneous error check result.

The LDPC code considered in the disclosure is a quasi-cyclic LDPC code that may be defined as a parity check matrix in a form of quasi-cyclic, as shown in FIGS. 3A and 3B, and has an algebraic characteristic according to a block size, which is usually represented as L or Z, as shown in Equation 11. For example, a cycle characteristic on a Tanner graph of the quasi-cyclic LDPC code is related to the block size, and if the parity check matrix is full rank, a length of the LDPC information code may also be represented in a form of a multiple of the block size. Due to this algebraic characteristic, the quasi-cyclic LDPC code may be encoded and decoded more efficiently based on a block length.

However, since a transport block generally has various lengths, the number of information word bits of the LDPC code, which may be defined in the parity check matrix of the quasi-cyclic LDPC code, that is, in a form of a multiple of a specific block size Z, may not necessarily be represented in such a form. Likewise, even after the segmentation described in FIG. 4, it may not be represented in the form of the multiple of the block size Z. As such, when encoding information word bits or a code block that are smaller than the maximum number of LDPC information word bits or the maximum code block size that may be LDPC-encoded at once with respect to the parity check matrix, or that are not in the form of the multiple of the block size, an additional operation such as zero padding (or shortening) may be performed to satisfy the multiple of the block size for convenience of encoding or decoding.

In general, in a wireless communication system, a data error may occur in the receiver due to noise existing in a communication channel. An encoding method designed to correct the error caused by the communication channel in the receiver is referred to as an error correction codes (ECC) technique. More particularly, the error correction codes technique used in communication between transceivers is referred to as channel coding. For example, according to the error correction codes technique, the transmitter transmits an additional bit along with a data bit, and the receiver may perform a decoding operation to correct an error included in the data bit based on the additional bit.

The above-described error correction codes may include convolutional coding, turbo coding, low-density parity-check coding (LDPC coding), and polar coding. The turbo coding and the LDPC coding may have performance close to a theoretical channel capacity.

Based on the above-described channel encoding technique, a hybrid automatic repeat request (HARQ) technique for increasing data transmission efficiency may be used. According to the HARQ technique, efficiency of resource use may be secured by transmitting to have a higher code rate than an optimal code rate required in a given channel. In addition, in a case that there is an error in the received data (hereinafter referred to as initial transmission data), the receiver may receive data (hereinafter referred to as retransmission data) retransmitted to the transmitter. The receiver may reduce a probability of error by summing an LLR value of the initial transmission data and an LLR value of the retransmission data. The HARQ technique may efficiently increase a throughput of the system.

According to an embodiment of the disclosure, the HARQ technique may include a chase combining HARQ (CC-HARQ) technique and an incremental redundancy HARQ (IR-HARQ) technique. The CC-HARQ technique is a technique for retransmitting data identical to the data sent in the initial transmission. The IR-HARQ technique is a technique in which a parity amount of a channel code transmitted for each data transmission is changed. In a case that the IR-HARQ technique is applied, there is an effect of obtaining an LLR combine gain and a channel code gain. Accordingly, the IR-HARQ technique is used in most communication standards (e.g., the 3GPP communication standards).

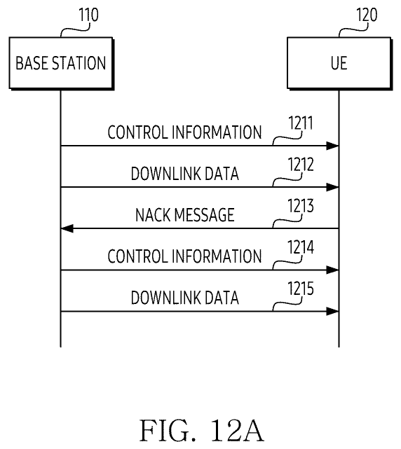

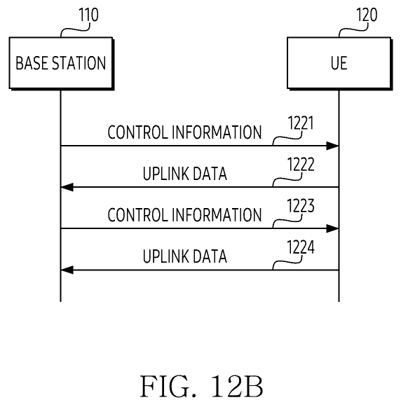

FIGS. 12A and 12B illustrate an operation of a base station and a terminal for an HARQ technique according to various embodiments of the disclosure.

Referring to FIG. 12A, an HARQ retransmission for downlink data is described, and in FIG. 12B, an HARQ retransmission for uplink data is described.

FIGS. 12A and 12B illustrate a base station 110 and a terminal 120 as a portion of nodes using a wireless channel in a wireless communication system. Although FIG. 1 illustrates only one base station, the wireless communication system may further include another base station identical to or similar to the base station 110.

The base station 110 is a network infrastructure for providing wireless access to the terminal 120. The base station 110 has coverage, defined based on a distance at which a signal may be transmitted. In addition to the base station, the base station 110 may be referred to as an “access point (AP), an “eNode B (eNB), a “5th generation node,” a “next generation node B (gNB), a “wireless point,” a “transmission/reception point (TRP),” or another term having a technical meaning equivalent thereto.

The terminal 120 is a device used by a user, and communicates with the base station 110 through the wireless channel. A link from the base station 110 to the terminal 120 is referred to as downlink (DL), and a link from the terminal 120 to the base station 110 is referred to as uplink (UL). In addition, although not illustrated in FIG. 1, the terminal 120 and another terminal may communicate with each other through the wireless channel. In this case, a device-to-device link (D2D) between the terminal 120 and the other terminal is referred to as a sidelink, and the sidelink may be used interchangeably with a PC5 interface. In some other embodiments of the disclosure, the terminal 120 may be operated without user involvement. According to an embodiment of the disclosure, the terminal 120 is a device that performs machine type communication (MTC), and may not be carried by the user. In addition, according to an embodiment of the disclosure, the terminal 120 may be a narrowband (NB)-Internet of things (IoT) device.

In addition to a terminal, the terminal 120 may be referred to as ‘user equipment (UE), ‘customer premises equipment (CPE), a ‘mobile station’, a ‘subscriber station’, a ‘remote terminal’, a ‘wireless terminal’, an ‘electronic device’, or a ‘user device’ or another term having a technical meaning equivalent thereto.

Referring to FIG. 12A, an example in which the HARQ technique is performed in the downlink is illustrated.

In operation 1211, the base station 110 may transmit control information to the terminal 120. For example, the control information may be transmitted through a physical downlink control channel (PDCCH). For example, the control information may include downlink control information (DCI). The DCI may include a position of a resource area of user data (e.g., PDSCH) and/or information necessary to decode the user data. For example, the DCI may have a DCI format 1_x (x=0, 1, 2, . . . ) of an NR standard. The DCI format 1_x may be used for resource allocation of downlink data (e.g., PDSCH). In addition, the DCI may include an HARQ process number related to downlink data, which is a target of scheduling. In addition, the DCI may include a new data indicator (NDI). According to whether a value of the NDI is toggled, whether resource allocation information of the DCI is for a retransmission, data, or a new transmission may be identified.

In operation 1212, the base station 110 may transmit the downlink data to the terminal 120. For example, the downlink data may be transmitted through the physical downlink shared channel (PDSCH). For example, the downlink data may be referred to as a transport block (TB). The TB may refer to data transmitted from the base station 110 to the terminal 120.

In operation 1213, the terminal 120 may transmit a NACK message to the base station 110. For example, the terminal 120 may detect a failure of decoding the downlink data. The terminal 120 may transmit a negative acknowledgement (NACK) message to the base station 110 based on detecting the failure of the decoding. For example, the NACK message may be transmitted through a physical uplink control channel (PUCCH). Unlike as illustrated in FIG. 12A, the terminal 120 may transmit an acknowledgement (ACK) message based on success of decoding the downlink data.

In operation 1214, the base station 110 may transmit control information to the terminal 120. For example, the control information may be transmitted through the PDCCH. In response to the NACK of operation 1213, the base station 110 may determine to transmit the downlink data again. The base station 110 may allocate a resource for a retransmission of the downlink data. The base station 110 may transmit the control information including resource allocation information on the downlink data for a retransmission to the terminal 120. The base station 110 may not toggle a value of NDI in order to inform the terminal 120 of the retransmission. For example, an ND value of the control information in operation 1214 may be the same as the value of the NDI included in the control information in operation 1211, to indicate the retransmission. The base station 110 may set the value of the NDI included in the control information to be the same as the value of the NDI included in the control information according to operation 1211 for the retransmission of the downlink data. The terminal 120 may identify that the value of the NDI is not toggled based on the control information. For example, the terminal 120 may identify that the value of the NDI in the control information according to operation 1214 is the same as the value of the NDI in the control information according to operation 1211. Although not illustrated in FIG. 12A, if the ACK message is transmitted instead of the NACK message in operation 1213, the terminal 120 may identify that new data is transmitted based on identifying that the value of the NDI has been toggled.

In operation 1215, the base station 110 may transmit downlink data to the terminal 120. For example, the downlink data may be transmitted through the PDSCH. For example, the base station may transmit the downlink data according to operation 1215 to retransmit the downlink data according to operation 1212. The terminal 120 may identify that downlink data for the retransmission has been received based on identifying that the value of the NDI of the PDCCH according to operation 1214 is not toggled.

The terminal 120 may perform decoding based on the retransmission of the downlink data. According to an embodiment of the disclosure, the terminal 120 may combine the downlink data received in operation 1212 with the downlink data received in operation 1215. The terminal 120 may decode the combined data. The terminal 120 may perform decoding through a combination (e.g., soft combining) of HARQ LLR of the downlink data received in operation 1212 and HARQ LLR of the downlink data received in operation 1215.

Referring to FIG. 12B, an example in which the HARQ technique is performed in the uplink is illustrated.

In operation 1221, the base station 110 may transmit control information to the terminal 120. For example, the control information may be transmitted through the PDCCH. For example, the control information may include DCI for resource allocation for the uplink. The DCI may include NDI. The DCI may include a position of a resource area of user data (e.g., PDSCH) and/or information necessary to decode the user data. For example, the DCI may have a DCI format 0_x (x=0, 1, 2, . . . ) of the NR standard. The DCI format 0_x may be used for the resource allocation of the uplink data. In addition, the DCI may include an HARQ process number related to downlink data, which is a target of scheduling. In addition, the DCI may include a new data indicator (NDI). According to whether a value of the NDI is toggled, whether resource allocation information of the DCI is for a retransmission, data, or a new transmission may be identified.

In operation 1222, the terminal 120 may transmit uplink data to the base station 110 based on the allocated resource. For example, the uplink data may be transmitted through PUSCH. For example, the uplink data may include TB. The TB may include MAC PDU that is data transmitted from the terminal 120 to the base station 110. The base station 110 may receive the uplink data from the terminal 120. The base station 110 may decode the uplink data. The base station 110 may identify whether the decoding of the uplink data is a success or a failure. Although a separate ACK or NACK is not transmitted to the terminal 120, the base station 110 may inform the terminal 120 of whether or not the transmission of the uplink data is successful in operation 1221 through a transmission of control information to be described later.

In operation 1223, the base station 110 may transmit control information to the terminal 120. The control information may include the resource allocation information on the uplink data. For example, the DCI may include an HARQ process number related to uplink data, which is a target to be retransmitted. The DCI may include the same HARQ process number as the HARQ process number of operation 1221. For example, the control information may include NDI. A value of the NDI included in the control information according to operation 1223 may be the same as a value of the NDI included in the control information according to operation 1221. A value of a non-toggled NDI may indicate a retransmission. The terminal 120 may identify that a retransmission of the uplink data is necessary based on identifying that the value of the NDI has been maintained.

In operation 1224, the terminal 120 may retransmit uplink data to the base station 110 based on the resource allocated through the control information according to operation 1223. For example, the uplink data may be transmitted through the PUSCH. The base station 110 may receive the retransmitted uplink data.

The base station 110 may perform decoding based on the retransmission of the uplink data. According to an embodiment of the disclosure, the base station 110 may combine the uplink data received in operation 1222 with the uplink data received in operation 1222. The base station 110 may decode the combined data. The base station 110 may perform decoding through a combination (e.g., soft combining) of

HARQ LLR of the uplink data received in operation 1222 and HARQ LLR of the uplink data received in operation 1215.

The operation of the base station 110 described in FIGS. 12A and 12B is described as being performed by the base station 110 which is a single network entity, but embodiments of the disclosure are not limited thereto. Operations of the base station 110 for describing the embodiments of the disclosure may be performed by a plurality of network entities (e.g., DU, and RU) in a distributed network. For example, an operation of receiving the uplink data may be performed by the RU, and an operation of decoding the uplink data may be performed by the DU. In addition, for example, an operation of determining the retransmission is performed by the DU, and an operation of retransmitting downlink data may be performed by the RU.

In the following specification, an operation of a transmitter and an operation of a receiver according to the HARQ technique (e.g., the IR-HARQ technique) are described. In a downlink data transmission, the transmitter exemplifies the base station 110 and the receiver exemplifies the terminal 120. In an uplink data transmission, the transmitter exemplifies the terminal 120 and the receiver exemplifies the base station 110. Meanwhile, in receiving uplink data, an operation of receiving the uplink data in an RF area may be performed by the RU of the base station 110, and an operation of decoding and demodulating the uplink data may be performed by the DU.

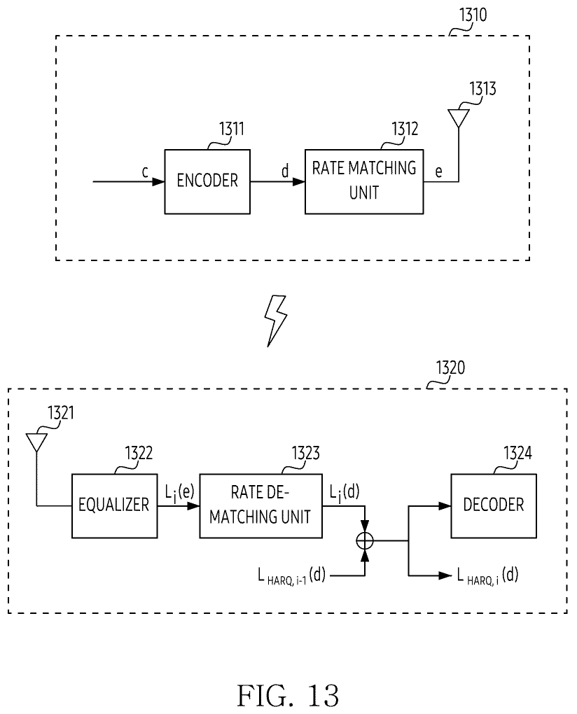

FIG. 13 illustrates a transceiver function block according to an IR-HARQ technique according to an embodiment of the disclosure.

Referring to FIG. 13, FIG. 13 illustrates a transport block 1310 for IR-HARQ among functional blocks of a transmitter and a reception block 1320 for IR-HARQ among components of a receiver.

The transmitter may include the transport block 1310 for IR-HARQ. The transport block 1310 may include an encoder 1311, a rate matching unit 1312, and an antenna 1313. A channel code bit (c) having a mother code rate may be encoded through the encoder 1311. As the channel code bit (c) is encoded through the encoder 1311, an encoding bit (d) may be obtained. As the encoding bit (d) is rate-matched through the rate matching unit 1312, a rate matching bit (e) having a code rate designated in the rate matching unit 1312 may be obtained. A transmission signal including the rate matching bit (e) may be transmitted to the receiver through the antenna 1313.

The receiver may include the reception block 1320 for IR-HARQ. The reception block 1320 may include an antenna 1321, an equalizer 1322, a rate de-matching unit 1323, and a decoder 1324. The receiver may receive a reception signal through the antenna 1321. The receiver may obtain a rate matching bit Li(e) through the equalizer 1322 based on the received signal. The receiver may obtain an encoding bit Li(d) through the rate de-matching unit 1333 based on the rate matching bit Li(e). By combining the encoding bit Li(d) with HARQ LLR (LHARQ, i−1(d)) obtained according to a previous transmission, HARQ LLR (LHARQ, i(d)) may be obtained. The receiver may perform decoding of HARQ LLR (LHARQ, i(d)) through the decoder 1334.

According to an embodiment of the disclosure, although not illustrated, a virtual buffer in which rate matching is performed may be included in the transmitter and the receiver. For example, the buffer may be referred to as a circular buffer or an IR buffer.

According to an embodiment of the disclosure, the receiver may further include HARQ LLR memory distinguished from the circular buffer. For example, the circular buffer may be used for combining HARQ LLR data. The HARQ LLR memory may be used to store the obtained HARQ LLR data. For example, the receiver may store first HARQ LLR data obtained based on a first signal in the HARQ LLR memory. The receiver may read the first HARQ LLR data from the HARQ LLR memory to combine LLR data according to a second signal and the first HARQ LLR data. The receiver may combine the first HARQ LLR data and the LLR data according to the second signal using the circular buffer. The receiver may obtain second HARQ LLR data based on combining the first HARQ LLR data and the LLR data according to the second signal. The receiver may perform decoding based on the second HARQ LLR data and store (or write) the second HARQ LLR data in the HARQ LLR memory.

For example, the circular buffer may be configured based on at least one parameter. For example, in a 5G standard where LDPC is used, a limit buffer rate matching (LBRM) technique may be used to reduce implementation complexity of a terminal. According to the LBRM technique, as a size of the circular buffer decreases, the implementation complexity may decrease. In a case that the LBRM technique is used, a size N_{cb} of the circular buffer may be set as shown in Equation 20.

$${N}_{c b} = min ( N , {N}_{r e f} ) \qquad Equation 20$$

In Equation 20, N_{cb} indicates the size of the circular buffer. N_{cb} may be set to a smaller value among N and Nref. N may be set based on Equation 21 below. N_{ref} may be set based on Equation 22 below. According to an embodiment of the disclosure, in a case that the LBRM technique is not applied, Neb may be set to N.

$$N = \{ \begin{matrix}66 \cdot {Z}_{c} , & base graph 1 \\ 50 \cdot {Z}_{c} , & base graph 2\end{matrix} \qquad Equation 21$$

Referring to Equation 21, according to base graph 1, a value of N may be set to 66·Z_{c}. According to base graph 2, a value of N may be set to 50·Z_{c}. Z_{c} means a lifting size for the LDPC. For example, Z_{c} may mean a size of a code block.

$${N}_{r e f} = ⌊ \frac{T B {S}_{L B R M}}{C \cdot {R}_{L B R M}} ⌋ \qquad Equation 22$$

In Equation 22, TBS_{LBRM} is the maximum size of TB calculated according to a standard. C is the number of code blocks set (or calculated) based on TBS_{LBRM}. R_{LBRM} is defined differently according to the standard. For example, R_{LBRM} may be set to ⅔ (2 over 3).

In the following specification, a technical characteristic for a channel decoder to read and write HARQ LLR data in the HARQ LLR memory may be described. Specifically, the technical characteristic for reading the HARQ LLR data stored in HARQ LLR memory in previous transmissions, necessary for channel decoding, may be explained. In addition, a technical characteristic for combining newly received LLR data with the HARQ LLR data stored in the HARQ LLR memory and additionally storing some of the combined HARQ LLR data in the HARQ LLR memory may be described.

According to an embodiment of the disclosure, the channel decoder may obtain all LLRs for the circular buffer from the HARQ LLR memory. For example, the receiver may provide the HARQ LLR data to the circular buffer based on reading the HARQ LLR data stored in the HARQ LLR memory. In addition, all HARQ LLRs combined on the circular buffer may be provided as the HARQ LLR memory. As an example, the receiver may provide all HARQ LLR data combined on the circular buffer to the HARQ LLR memory.

In some communication standards (e.g., 3GPP standard), a mother code rate of the circular buffer is defined as ⅓. Accordingly, a size of the circular buffer may be about 3·K. In a case that LDPC is used, the size N of the circular buffer may be set based on Equation 21 described above.

In a case of the IR-HARQ technique, a redundancy version parameter may be used to adjust an amount of a parity code to be transmitted. The redundancy version parameter may be used to designate a position at which rate matching starts in the circular buffer. A redundancy version may be set differently for each transmission. For example, a pseudo code for rate matching based on the redundancy version may be set as shown in Table 1.

TABLE 1

```
k = 0;
j = 0;
while k < E
  if d₍ₖ_{ₒ}_{+j)mod N}_{_{cb}} ≠< NULL >
    eₖ = d₍ₖ_{ₒ}_{+j)mod N}_{_{cb}};
    k = k + 1;
  end if
  j = j + 1;
end while
```

For example, a start position k₀ in the circular buffer according to the redundancy version may be set as shown in Table 2.

TABLE 2

| | k₀ | |
|---|---|---|
| rv_{id} | LDPC base graph 1 | LDPC base graph 2 |
| 0 | 0 | 0 |
| 1 | $⌊ \frac{17 {N}_{cb}}{66 {Z}_{c}} ⌋ {Z}_{c}$ | $⌊ \frac{13 {N}_{cb}}{50 {Z}_{c}} ⌋ {Z}_{c}$ |
| 2 | $⌊ \frac{33 {N}_{cb}}{66 {Z}_{c}} ⌋ {Z}_{c}$ | $⌊ \frac{25 {N}_{cb}}{50 {Z}_{c}} ⌋ {Z}_{c}$ |
| 3 | $⌊ \frac{56 {N}_{cb}}{66 {Z}_{c}} ⌋ {Z}_{c}$ | $⌊ \frac{43 {N}_{cb}}{50 {Z}_{c}} ⌋ {Z}_{c}$ |

According to an NR standard, complexity of channel decoding has increased as a data rate specification required is higher compared to the LTE standard. More particularly, according to the NR standard, requirements for the HARQ LLR memory storing HARQ LLR have increased. Additionally, high hardware throughput may be required to read and write HARQ LLR data into the HARQ LLR memory since the number of LLRs that should be processed per unit time is increased due to the increased data rate. Accordingly, the LBRM technique, and a code block group (CBG) HARQ technique to retransmit only some code blocks that failed to be decoded, have been proposed. However, according to the LBRM technique, performance reduction occurs. According to the CBG HARQ technique, complexity of a scheduler for resource allocation is increased, making it difficult to implement. Therefore, a technical characteristic for reading and writing only a portion of the HARQ LLR memory may be described below. For example, a data rate described below may mean a data processing (e.g., data transfer) speed of memory. As an example, the data rate may refer to a speed for reading or writing data in the memory.

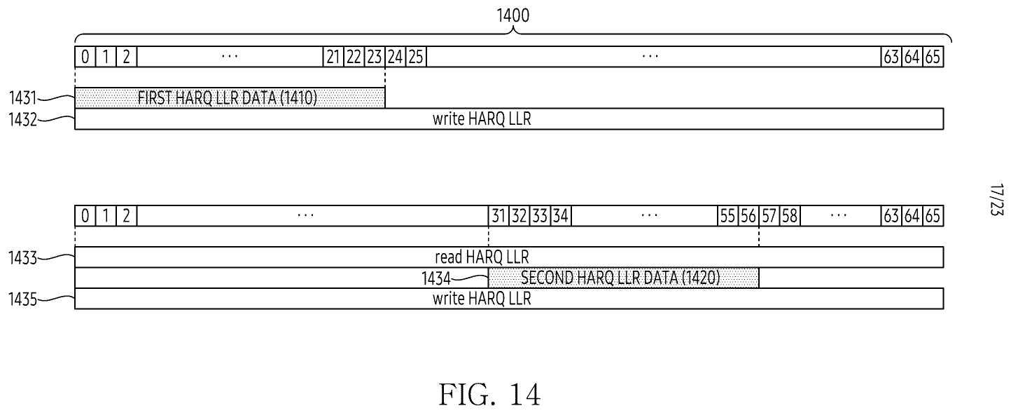

FIG. 14 illustrates an operation for reading and writing HARQ LLR data stored in HARQ LLR memory in a circular buffer according to an embodiment of the disclosure.

Referring to FIG. 14, a circular buffer 1400 included in a receiver may include an area for storing 66·Z_{c} code bits. One space of the circular buffer 1400 may mean Z_{c} code bits. The receiver may read the HARQ LLR data stored in the HARQ LLR memory for decoding and store the HARQ LLR data in the circular buffer. The receiver may store the HARQ LLR data stored in the circular buffer in the HARQ LLR memory.

In operation 1431, the receiver (or a processor of the receiver) may receive a first signal related to an initial transmission of a transport block. The receiver may obtain first HARQ LLR data 1410 based on the first signal. The receiver may store the first HARQ LLR data 1410 in the circular buffer.

In operation 1432, the receiver (or the processor of the receiver) may write, in order to store the first HARQ LLR data 1410 in HARQ LLR memory (not illustrated), HARQ LLR values including the first HARQ LLR data 1410 in the HARQ LLR memory. For example, the HARQ LLR values may refer to all values stored in the circular buffer 1400.

The receiver may store the first HARQ LLR data 1410 in an area configured as an address 0 to an address 23×Z_{c}, based on writing the HARQ LLR values in the HARQ LLR memory.

In operation 1433, the receiver may receive a second signal related to a first retransmission of the transport block. The receiver may read HARQ LLR values stored in the entire area of the HARQ LLR memory based on the reception of the second signal. The receiver may store the HARQ LLR values in the circular buffer 1400 based on reading the HARQ LLR values stored in the entire area of the HARQ LLR memory. The receiver may obtain the first HARQ LLR data 1410 based on reading the HARQ LLR values stored in the entire area of the HARQ LLR memory.

In operation 1434, the receiver may obtain second HARQ LLR data 1420 based on the second signal related to the first retransmission of the transport block. The receiver may store the first HARQ LLR data 1410 in the circular buffer 1400.

In operation 1435, the receiver (or the processor of the receiver) may write HARQ LLR values including the first HARQ LLR data 1410 and the second HARQ LLR data 1420 to the entire area of the HARQ LLR memory, in order to store the first HARQ LLR data 1410 and the second HARQ LLR data 1420 in the HARQ LLR memory. For example, the HARQ LLR values may refer to all values stored in the circular buffer 1400.

The receiver may store the first HARQ LLR data 1410 in an area configured as an address 0×Z_{c} to an address 23×Z_{c}, and store the second HARQ LLR data 1420 in an area configured as an address 33×Z_{c} to an address 56×Z_{c}, based on writing of HARQ LLR values in the HARQ LLR memory.

As in the above-described embodiment of the disclosure, the receiver may obtain the stored HARQ LLR data (e.g., the first HARQ LLR data 1410 and/or the second HARQ LLR data 1420) based on reading the entire area of the HARQ LLR memory. The receiver may store the HARQ LLR data (e.g., the first HARQ LLR data 1410 and/or the second HARQ LLR data 1420) in the HARQ LLR memory based on writing the entire area of the HARQ LLR memory.

According to an embodiment of the disclosure, in a case that a code rate is high due to a characteristic of an IR-HARQ technique, only a portion of the circular buffer (or the HARQ LLR memory) may be used. For example, HARQ LLR data exists only in the portion of the circular buffer (or the HARQ LLR memory), and a value of a remaining area of the circular buffer is set to a designated value (e.g., ‘0’). Therefore, when the HARQ LLR data may be read or written only in an area where the HARQ LLR data is stored (or exists), performance loss may be reduced compared to reading and writing all HARQ LLR data in the circular buffer (or the HARQ LLR memory), and hardware requirements for reading and writing the HARQ LLR data may be lowered. As an example, in a case that the receiver reads or writes the HARQ LLR data only in the area where the HARQ LLR data is stored (or exists), the performance loss may not occur.

Therefore, hereinafter, by identifying the area of the circular buffer where the HARQ LLR data exists for each transmission, a channel decoder may reduce performance loss, and a technical characteristic for reading and writing the HARQ LLR data required for decoding may be explained. For example, at least one parameter related to the circular buffer and at least one parameter related to the rate matching technique may be used for the technical characteristic.

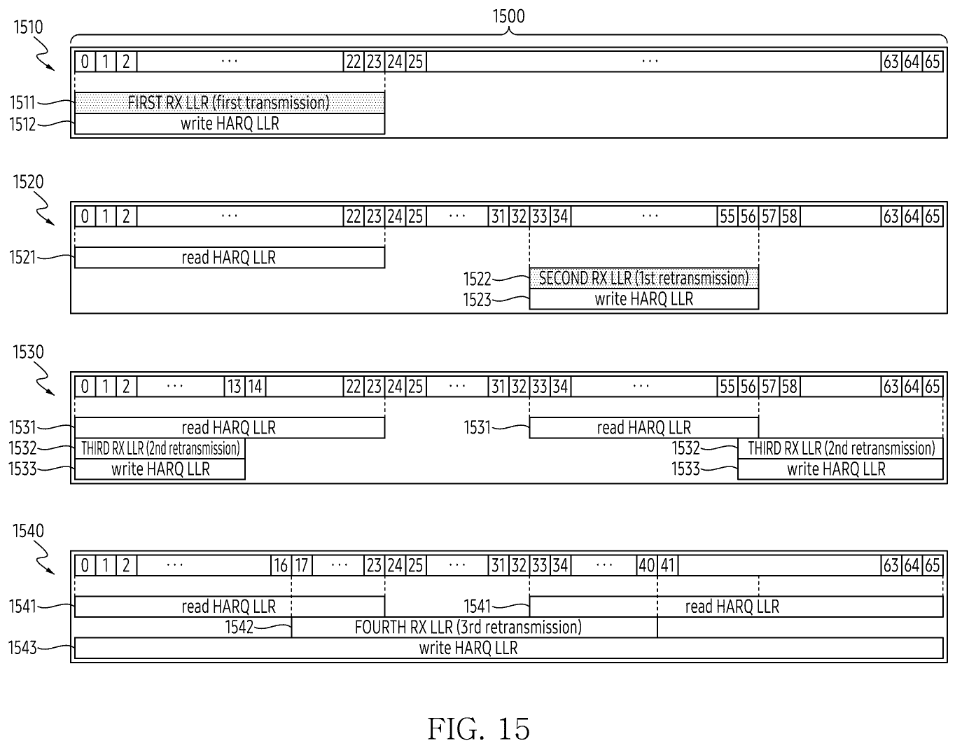

FIG. 15 illustrates reading and writing a partial area of HARQ LLR memory in a circular buffer according to an embodiment of the disclosure.

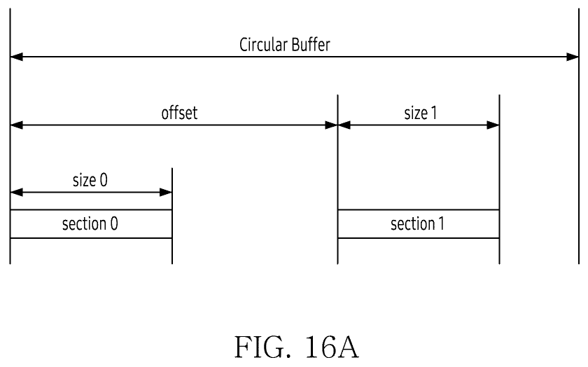

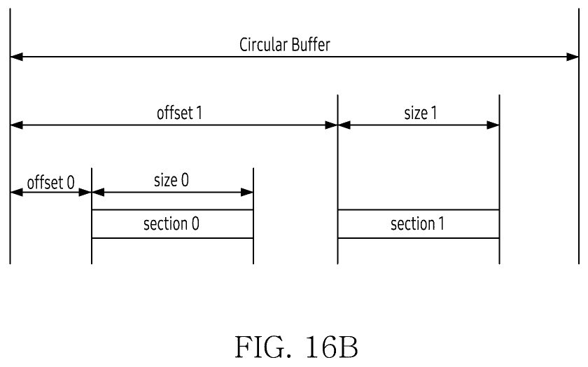

FIGS. 16A and 16B illustrate parameters for identifying a position of HARQ LLR data according to various embodiments of the disclosure.

Referring to FIGS. 15, 16A, and 16B, a receiver may read HARQ LLR data stored in the HARQ LLR memory to perform an HARQ operation. The receiver may perform an HARQ combining operation based on storing the HARQ LLR data in a circular buffer 1500.

According to an embodiment of the disclosure, the circular buffer 1500 and the HARQ LLR memory (not illustrated) may be configured to have the same size.

For example, in a case that the HARQ LLR data stored in the circular buffer 1500 should be stored in the HARQ LLR memory, the receiver may store the HARQ LLR data in the HARQ LLR memory based on the same address as an address where the HARQ LLR data is stored in the circular buffer 1500.

For example, in a case that the receiver needs to store the HARQ LLR data stored in the HARQ LLR memory in the circular buffer 1500 for decoding, the HARQ LLR data may be stored in the circular buffer 1500 based on the same address as the address where the HARQ LLR data is stored in the HARQ LLR memory.

Referring to FIG. 15, a size of the circular buffer 1500 may be set based on base graph 1 according to an NR standard. For example, the number of code bits may be set to 68×Z_{c} based on the base graph 1. The size of the circular buffer 1500 may be set to a remaining 66×Z_{c} except for a first 2×Z_{c} code bits from 68×Z_{c} code bits. Therefore, as only the code bit of 66×Z_{c} is mapped to the circular buffer, a portion defined according to a redundancy version and a rate matching size may be transmitted. Although FIG. 15 illustrates the circular buffer 1500 set based on the base graph 1, it is not limited thereto. According to an embodiment of the disclosure, a circular buffer based on base graph 2 may be set. A size of the circular buffer set based on the base graph 2 may be set to 50×Z_{c}.

In operations 1511 to 1543, RX LLR may mean LLR data for bits actually transmitted for each transmission. A ‘write HARQ LLR’ operation may mean an area in which the HARQ LLR data stored in the HARQ LLR memory and the received LLR data are combined in a previous transmission to be updated in the HARQ LLR memory. A ‘read HARQ LLR’ operation may mean an area in which a channel decoder should read in the HARQ LLR memory for decoding.

The receiver should know a position where the HARQ LLR data is stored in order to read the HARQ LLR data stored in the HARQ LLR memory. In addition, the receiver should know a position where the HARQ LLR data will be stored in order to store the HARQ LLR data in the HARQ LLR memory. Therefore, a parameter indicating a position of the HARQ LLR data to be read in the circular buffer and a parameter indicating a position of the HARQ LLR data to be written may be required. To identify the position of the HARQ LLR data, parameters illustrated in FIG. 16A or 16B may be used.

Referring to FIG. 16A, the HARQ LLR data to be read and written in the circular buffer (or the HARQ LLR memory) may be divided into two sections. For example, two sections may be referred to as a section 0 (or an HARQ LLR section 0) and a section 1 (or an HARQ LLR section 1). The section 0 may always start from the beginning (e.g., an address 0 of the circular buffer 1500) of the circular buffer. The section 1 may start from any position in the circular buffer.

Referring to FIG. 16B, the HARQ LLR data to be read and written in the circular buffer (or the HARQ LLR memory) may be divided into two sections. For example, two sections may be referred to as a section 0 (or an HARQ LLR section 0) and a section 1 (or an HARQ LLR section 1). The section 0 and the section 1 may start from any position in the circular buffer. An offset 0 indicating a start position of the section 0 may be set to be less than an offset 1 indicating a start position of the section 1.

In FIG. 16A, an area for reading or writing the HARQ LLR data in the circular buffer (or the HARQ LLR memory) may be indicated by a size of the section 0, a size of the section 1, the offset 0, and the offset 1. In FIG. 16B, an area for reading or writing the HARQ LLR data in the circular buffer (or the HARQ LLR memory) may be indicated by a size of the section 0, a size of the section 1, the offset 0, and the offset 1.

For convenience of explanation, a specific example in which the area for reading or writing the HARQ LLR data is indicated through the section 0, the section 1, and the offset according to FIG. 16A will be described based on FIG. 15.

Referring back to FIG. 15, the receiver may perform operation 1511 and operation 1512 for an initial transmission 1510. A signal of the initial transmission 1510 may include data of a redundancy version 0 (i.e., RV 0). For a first retransmission 1520, the receiver may perform operation 1521 to operation 1523. The first retransmission 1520 may include data of a redundancy version 2. For a second retransmission 1530, the receiver may perform operation 1531 to operation 1533. The second retransmission 1530 may include data of a redundancy version 3. For a third retransmission 1540, the receiver may perform operation 1541 to operation 1543. The third retransmission 1540 may include data of a redundancy version 1.

For example, a code rate for an IR-HARQ retransmission may be set to 9/10. An order of a redundancy version and the code rate for the IR-HARQ retransmission are and may be changed.

In operation 1511 within operation 1510, the receiver may receive a first signal related to an initial transmission of a transport block. The receiver may obtain first RX LLR data based on the first signal. For example, the receiver may store the first RX LLR data in a first area of the circular buffer 1500. The first area may be configured as an address 0 to an address 23×Z_{c} of the circular buffer 1500.

In operation 1512 within operation 1510, the receiver may write the first RX LLR data to the HARQ LLR memory. The receiver may write the first RX LLR data to the first area of the HARQ LLR memory. Since the circular buffer 1500 and the HARQ LLR memory are set to be the same, a first area of the circular buffer 1500 may correspond to the first area of the HARQ LLR memory.

As it is the initial transmission, since the receiver has all values of the HARQ LLR memory, all of the first RX LLR data should be stored in the HARQ LLR memory. Therefore, position information of the first area on the circular buffer may be set as shown in the following equation. In the following equations (e.g., Equation 23 to Equation 28), a ‘section 0’ field means a size of the section 0. A ‘section 1’ field means a size of the section 1. An ‘offset’ field means a start position of the section 1.

(section 0, offset, section 1)=(24×Z_{c}, 0, 0) (23)

Referring to Equation 23, since the first area is configured as one continuous part, the first area may be indicated by only the section 0. Accordingly, the first area may be indicated as shown in Equation 23.

In operation 1521 within operation 1520, the receiver may receive a second signal related to a first retransmission of the transport block. The receiver may read first HARQ LLR data stored in the HARQ LLR memory based on the second signal. The first HARQ LLR data may correspond to the first RX LLR data.

The receiver may read the first HARQ LLR data stored in the HARQ LLR memory by indicating an area in which the first HARQ LLR data is stored based on Equation 23. The receiver may store the first HARQ LLR data in the circular buffer 1500.

In operation 1522 within operation 1520, the receiver may obtain second RX LLR data based on a second signal. As it is the first retransmission, a redundancy version may be ‘2’ (i.e., RV 2). The receiver may combine the first HARQ LLR data and the second RX LLR data for decoding. The combined LLR data may be configured as two portions of an address 0 to an address 23×Z_{c} and an address 33×Z_{c} to an address 56×Z_{c}. Herein, a portion of the HARQ LLR memory that needs to be updated may be a second area in which second RX LLR data is stored. Accordingly, the receiver may store the second RX LLR data in the second area of the circular buffer 1500. The second area may be configured as an address 33×Z_{c} to an address 56×Z_{c} of the circular buffer 1500.

In operation 1523 within operation 1520, the receiver may write second HARQ LLR data to the HARQ LLR memory. The receiver may write the second HARQ LLR data in a second area of the HARQ LLR memory to update the second HARQ LLR data in the second area of the HARQ LLR memory. Since the circular buffer 1500 and the HARQ LLR memory are set to be the same, the second area of the circular buffer 1500 may correspond to the second area of the HARQ LLR memory. Position information of the second area on the circular buffer 1500 may be set as shown in the following equation.

$$( section 0 , offset , section 1 ) = ( 0 , 33 \times {Z}_{c} , 24 \times {Z}_{c} ) \qquad Equation 24$$

Referring to Equation 24, since the second area does not start from an address 0 but is configured as one continuous part, the second area may be indicated by the offset and the section 1. Accordingly, the second area may be indicated as shown in Equation 24.

In operation 1531 within operation 1530, the receiver may receive a third signal related to a second retransmission of the transport block. The receiver may read the first HARQ LLR data and the second HARQ LLR data stored in the HARQ LLR memory based on the third signal. The second HARQ LLR data may correspond to the second RX LLR data.

The receiver may read the first HARQ LLR data and the second HARQ LLR data stored in the HARQ LLR memory by indicating an area in which the first HARQ LLR data and the second HARQ LLR data are stored based on Equation 25 below. The receiver may store the first HARQ LLR data and the second HARQ LLR data in the circular buffer 1500.

$$( section 0 , offset , section 1 ) = ( 24 \times {Z}_{c} , 33 \times {Z}_{c} , 24 \times {Z}_{c} ) \qquad Equation 25$$

Referring to Equation 25, the first HARQ LLR data may be in a state of being stored in the first area and the second HARQ LLR data may be in a state of being stored in the second area. Therefore, a value indicating the size of the section 0 may be set to 24×Z_{c}. The offset may be set to 33×Z_{c}. A value indicating the size of the section 1 may be set to 24×Z_{c}.

In operation 1532 within operation 1530, the receiver may obtain third RX LLR data based on the third signal. As it is the second retransmission, a redundancy version may be ‘3’ (i.e., RV 3). The receiver may combine the first HARQ LLR data, the second HARQ LLR data, and the third RX LLR data for decoding. The combined LLR data may be configured as two portions of an address 0 to an address 23×Z_{c} and an address 33×Z_{c} to an address 65×Z_{c}. Herein, a portion of the HARQ LLR memory that needs to be updated may be a third area in which the third RX LLR data is stored. Accordingly, the receiver may store the third RX LLR data in the third area of the circular buffer 1500. The third area may be configured as an address 0 to an address 13×Z_{c} and an address 56×Z_{c} to an address 65×Z_{c} of the circular buffer 1500.

In operation 1533 within operation 1530, the receiver may write the third RX LLR data to the HARQ LLR memory. The receiver may write the third RX LLR data to the third area of the HARQ LLR memory to update the third RX LLR data in the third area of the HARQ LLR memory. Since the circular buffer 1500 and the HARQ LLR memory are set to be the same, the third area of the circular buffer 1500 may correspond to the third area of the HARQ LLR memory. Position information of the third region on the circular buffer 1500 may be set as shown in the following equation.

$$( section 0 , offset , section 1 ) = ( 14 \times {Z}_{c} , 56 \times {Z}_{c} , 10 \times {Z}_{c} ) \qquad Equation 26$$

Referring to Equation 26, since the third area configured as two divided parts, the third area may be indicated by the section 0, the offset, and the section 1. Therefore, the third area may be indicated as shown in Equation 26.

Since the third area overlaps a portion of the first area and a portion of the second area, at least a portion of the first HARQ LLR data and at least a portion of the second HARQ LLR data may be updated (or changed) based on the third RX LLR data.

In operation 1541 within operation 1540, the receiver may receive a fourth signal related to a third retransmission of the transport block. The receiver may read the first HARQ LLR data, the second HARQ LLR data, and third HARQ LLR data stored in the HARQ LLR memory based on the fourth signal. The third HARQ LLR data may correspond to the third RX LLR data.

The receiver may read the first HARQ LLR data to the third HARQ LLR data stored in the HARQ LLR memory by indicating an area in which the first HARQ LLR data to the third HARQ LLR data are stored based on Equation 27. The receiver may store the first HARQ LLR data to the third HARQ LLR data in the circular buffer 1500.

$$( section 0 , offset , section 1 ) = ( 24 \times {Z}_{c} , 33 \times {Z}_{c} , 33 \times {Z}_{c} ) \qquad Equation 27$$

Referring to Equation 27, an area configured by the first area to the third area may be configured as an address 0 to an address 23×Z_{c} and an address 33×Z_{c} to an address 65×Z_{c} of the HARQ LLR memory. Therefore, a value indicating the size of the section 0 may be set to 24×Z_{c}. The offset may be set to 33×Z_{c}. A value indicating the size of the section 1 may be set to 33×Z_{c}.

In operation 1542 within operation 1540, the receiver may obtain fourth RX LLR data based on the fourth signal. As it is the third retransmission, a redundancy version may be ‘1’ (i.e., RV 1). The receiver may combine the first HARQ LLR data, the second HARQ LLR data, the third HARQ LLR data, and the fourth RX LLR data for decoding. The combined LLR data may be configured as an entire area of the circular buffer from an address 0 to an address 65×Z_{c}. Herein, a portion of the HARQ LLR memory that needs to be updated may be the fourth area in which the fourth RX LLR data is stored. Accordingly, the receiver may store the fourth RX LLR data in the fourth area of the circular buffer 1500. The fourth area may be configured as an address 17×Z_{c} to an address 40×Z_{c} of the circular buffer 1500.

In operation 1543 within operation 1540, the receiver may write the fourth RX LLR data to the HARQ LLR memory. The receiver may write the fourth RX LLR data to the fourth area of the HARQ LLR memory to update the fourth RX LLR data to the fourth area of the HARQ LLR memory. Since the circular buffer 1500 and the HARQ LLR memory are set to be the same, the fourth area of the circular buffer 1500 may correspond to the fourth area of the HARQ LLR memory. Position information of the fourth area on the circular buffer 1500 may be set as shown in the following equation.

$$( section 0 , offset , section 1 ) = ( 0 , 17 \times {Z}_{c} , 24 \times {Z}_{c} ) \qquad Equation 28$$

Referring to Equation 28, since the fourth area does not start from an address 0 but is configured as one continuous part, the fourth area may be indicated by the offset and the section 1. Accordingly, the fourth area may be indicated as shown in Equation 28.

In operation 1510 to operation 1540, an example in which the first area to the fourth area are indicated through the ‘section 0’ field, the ‘offset’ field, and the ‘section 1’ field according to FIG. 16A has been described, but the first area to the fourth area may be indicated through the ‘section 0’ field, the ‘offset 0’ field, the ‘section 1’ field, and the ‘offset 1’ field according to FIG. 16B. In the following equations (e.g., Equation 29 to Equation 34), the ‘section 0’ field means a size of the section 0. The ‘section 1’ field means a size of the section 1. The ‘offset 0’ field means a start position of the section 0. An ‘offset 1’ field means a start position of the section 1.

Referring to FIG. 16B, position information of the first area on the circular buffer may be set as shown in the following equation.

$$( offset 0 , section 0 , offset 1 , section 1 ) = ( 0 , 24 \times {Z}_{c} , 0 , 0 ) \qquad Equation 29$$

Position information of the second area on the circular buffer 1500 may be set as shown in the following equation.

$$( offset 0 , section 0 , offset 1 , section 1 ) = ( 0 , 0 , 33 \times {Z}_{c} , 24 \times {Z}_{c} ) \qquad Equation 30$$

The receiver may read the first HARQ LLR data and the second HARQ LLR data stored in the HARQ LLR memory by indicating an area in which the first HARQ LLR data and the second HARQ LLR data re stored based on Equation 31 below. The receiver may store the first HARQ LLR data and the second HARQ LLR data in the circular buffer 1500.

$$( offset 0 , section 0 , offset 1 , section 1 ) = ( 0 , 24 \times {Z}_{c} , 33 \times {Z}_{c} , 24 \times {Z}_{c} \qquad Equation 31$$

Position information of the third area on the circular buffer 1500 may be set as shown in the following equation.

$$( offset 0 , section 0 , offset 1 , section 1 ) = ( 0 , 14 \times {Z}_{c} , 56 \times {Z}_{c} , 10 \times {Z}_{c} ) \qquad Equation 32$$

The receiver may read the first HARQ LLR data to the third HARQ LLR data stored in the HARQ LLR memory by indicating an area in which the first HARQ LLR data to the third HARQ LLR data are stored based on Equation 33. The receiver may store the first HARQ LLR data to the third HARQ LLR data in the circular buffer 1500.

$$( offset 0 , section 0 , offset 1 , section 1 ) = ( 0 , 24 \times {Z}_{c} , 33 \times {Z}_{c} , 33 \times {Z}_{c} ) \qquad Equation 33$$

Position information of the fourth area on the circular buffer 1500 may be set as shown in the following equation.

$$( offset 0 , section 0 , offset 1 , section 1 ) = ( 0 , 0 , 17 \times {Z}_{c} , 24 \times {Z}_{c} ) \qquad Equation 34$$

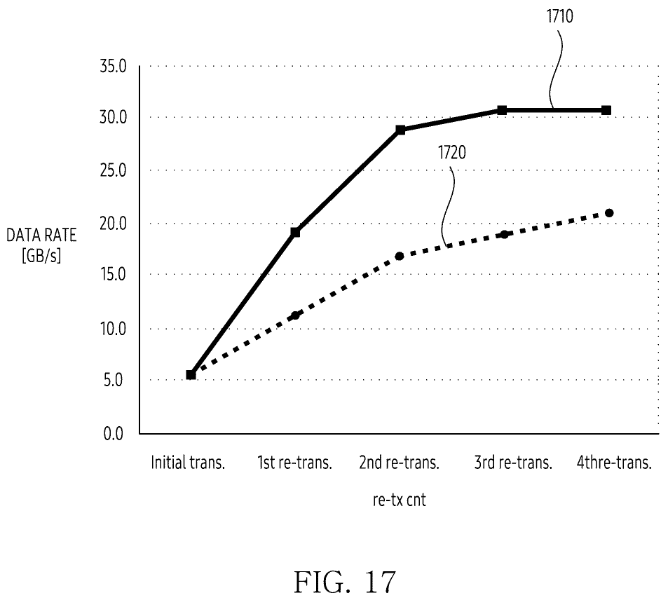

According to the above-described embodiment of the disclosure, performance loss may be reduced (or removed), and a data rate required for LLR input/output may be reduced. A change in the data rate according to the above-described embodiment will be illustrated in FIG. 17.

FIG. 17 illustrates a change in a data rate according to a partial HARQ LLR input/output technique according to an embodiment of the disclosure.

Referring to FIG. 17, the embodiment described in FIG. 14 may be referred to as a full HARQ LLR input/output technique. The embodiment described in FIG. 15 may be referred to as the partial HARQ LLR input/output technique.

A data rate according to the full HARQ LLR input/output technique and the partial HARQ LLR input/output technique may be configured as shown in Table 3.

TABLE 3

HARQ

LLR

| [symbol] | 1st re-transmission | | | 2nd re-transmission | | | 3rd re-transmission | | | 4th re-transmission | | |
|---|---|---|---|---|---|---|---|---|---|---|---|---|
| [symbol] | Total | Read | Write | Total | Read | Write | Total | Read | Write | Total | Read | Write |
| Full | 18.9 | 5.6 | 13.3 | 28.6 | 13.3 | 15.4 | 30.7 | 15.4 | 15.4 | 30.7 | 15.4 | 15.4 |
| Partial | 11.2 | 5.6 | 5.6 | 16.8 | 11.2 | 5.6 | 18.9 | 13.3 | 5.6 | 20.9 | 15.4 | 5.6 |

Referring to Table 3, Table 3 is an HARQ LLR input/output data rate required to perform an HARQ function for an MCS=27, 273 RB, 4-layer terminal in an environment where subcarrier spacing is set to 30 kHz (or slot=0.5 ms).

Generally, since a third retransmission is set to the last retransmission (i.e., RV 1) of an IR-HARQ retransmission, a change in the data rate may be compared based on the third retransmission.

According to the partial HARQ LLR input/output technique, a data rate of 18.9 Gbps may be required in the third retransmission. According to the full HARQ LLR input/output technique, a data rate of 30.7 Gbps may be required in the third retransmission. The data rate required for the third retransmission according to the full HARQ LLR input/output technique may be 62% higher than the data rate required for the third retransmission according to the partial HARQ LLR input/output technique. Therefore, according to the partial HARQ LLR input/output technique, there is reduction effect in the HARQ LLR rate of about 42% compared to the full HARQ LLR input/output technique.

FIG. 17 indicates graphs for Table 3. A horizontal axis of a graph 1710 or 1720 indicates the number of transmissions, and a vertical axis of the graph 1710 or 1720 indicates a data rate (e.g., GB/s).

The graph 1710 indicates a change in a data rate according to retransmission in a case that the full HARQ LLR input/output technique is applied. The graph 1720 indicates a change in a data rate according to retransmission in a case that the partial HARQ LLR input/output technique is applied.

According to the graph 1710 and the graph 1720, the data rate required for the third retransmission in the partial HARQ LLR input/output technique may be similar to the data rate required for the first retransmission in the full HARQ LLR input/output technique. In other words, when there is a receiver with a limited HARQ LLR data rate of 20 GB/s, the receiver may only retransmit once with the full HARQ LLR input/output technique, but the receiver may perform the third retransmission in the partial HARQ LLR input/output technique. Therefore, in a case that the partial HARQ LLR input/output technique is used in the receiver with limited HARQ data rate, performance may be improved.

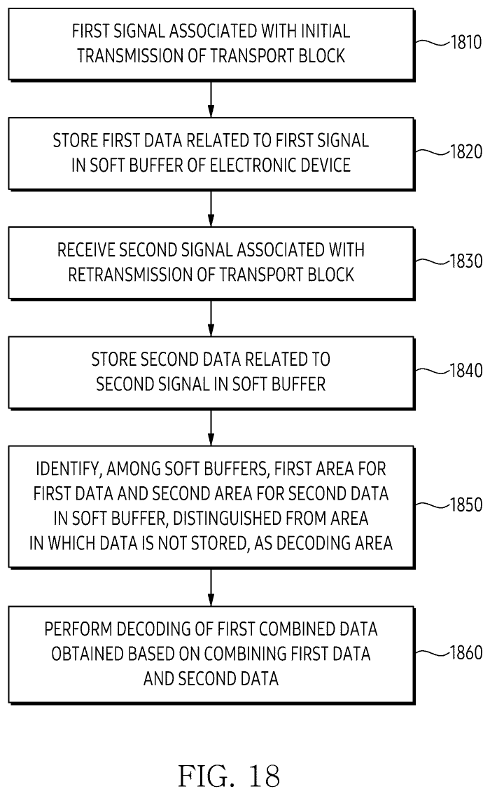

FIG. 18 illustrates a flowchart related to an operation of an electronic device for a partial HARQ LLR input/output technique according to an embodiment of the disclosure.

For example, the electronic device may include the base station 110, the terminal 120, and the device (e.g., DU, or RU) of the base station 110 of FIGS. 12A and 12B.

Referring to FIG. 18, in operation 1810, the electronic device (e.g., a receiver) (or a processor of the electronic device) may receive a first signal associated with an initial transmission of a transport block. The electronic device may receive the first signal associated with the initial transmission of the transport block from another electronic device (e.g., a transmitter). For example, the operation of receiving the first signal from a terminal may mean an operation in which DU of the electronic device receives the first signal from RU.

In operation 1820, the electronic device may store first data related to the first signal in a soft buffer (e.g., a circular buffer or HARQ LLR memory) of the electronic device. For example, based on a failure to decode the first signal, the first data related to the first signal may be stored in the soft buffer of the electronic device. For example, the first data may be associated with LLR data related to the first signal. For example, the operation of storing the first data related to the first signal may be performed in the DU of the electronic device. The DU of the electronic device may perform the operation of storing the first data related to the first signal in the soft buffer based on the failure to decode the first signal.

In operation 1830, the electronic device may receive a second signal associated with a retransmission of the transport block. For example, the electronic device may transmit a signal indicating NACK to the other electronic device based on the failure to decode the first signal. The electronic device may receive the second signal based on the signal indicating the NACK. For example, the electronic device may not transmit a response to the first signal to the other electronic device based on the failure to decode the first signal. The electronic device may receive the second signal based on not transmitting the response to the first signal. For example, the operation of receiving the second signal from the terminal may mean an operation in which the DU of the electronic device receives the second signal from the RU.

In operation 1840, the electronic device may store second data related to the second signal in the soft buffer. For example, the second data may be associated with LLR data related to the second signal. For example, the electronic device may obtain the second data based on the second signal. The electronic device may store the obtained second data in the soft buffer. For example, the operation of storing the second data related to the second signal may be performed in the DU of the electronic device. The DU of the electronic device may perform the operation of storing second data related to the second signal in the soft buffer based on the second signal.

In operation 1850, the electronic device may identify, among the soft buffers, a first area for the first data and a second area for the second data in the soft buffer, distinguished from an area in which data is not stored, as a decoding area. For example, the electronic device may identify a decoding area within the soft buffer to perform decoding. The electronic device may identify the first area in which the first data is stored and the second area in which the second data is stored as the decoding area. The electronic device may obtain (or identify) the first data in the first area. The electronic device may obtain (or identify) the second data in the second area. For example, the operation of identifying the first area for the first data and the second area for the second data as the decoding area may be performed in the DU of the electronic device. The DU of the electronic device may perform the operation of identifying the first area for first data and the second area for the second data as the decoding area based on the second signal.

In operation 1860, the electronic device may perform decoding of first combined data obtained based on combining the first data and the second data. The electronic device may combine the first data and the second data. The electronic device may obtain the first combined data based on the combining the first data and the second data. The electronic device may perform decoding based on the first combined data. For example, the operation of combining the first data and the second data and decoding the first combined data may be performed in the DU of the electronic device.

According to an embodiment of the disclosure, the electronic device may receive a third signal associated with a second retransmission of the transport block based on a failure to decode the first combined data. The electronic device may store third data for the third signal in a third area of the soft buffer. The electronic device may change the decoding area to an area excluding an area in which data is not stored from an entire area of the soft buffer. The electronic device may reduce a data rate by identifying the area excluding the area in which the data is not stored as the decoding area. The electronic device may perform decoding of second combined data obtained based on combining the first data to the third data, based on the changed decoding area.

For example, the electronic device may receive a fourth signal associated with a third retransmission of the transport block based on a failure to decode the second combined data. The electronic device may store fourth data for the fourth signal in a fourth area of the soft buffer. The electronic device may change the decoding area to the entire area of the soft buffer. The electronic device may perform decoding of third combined data obtained based on combining the first data to the fourth data based on the changed decoding area.

As an example, the first area to the fourth area may include the entire area of the soft buffer. There may be no area in which the data is not stored in the soft buffer. Therefore, the electronic device may set the entire area of the soft buffer as the decoding area.

For example, the third area may include at least a portion of the second area. The fourth area may include at least a portion of the first area and at least another portion of the second area.

For example, the first signal to the fourth signal may be transmitted based on an IR-HARQ technique. As an example, the first signal may be configured based on a redundancy version 0 (RV 0). The second signal may be configured based on RV 2. The third signal may be configured based on RV 3. The fourth signal may be configured based on RV 1. According to an embodiment of the disclosure, a redundancy version (RV) of the first signal to the fourth signal may be changed. For example, the first signal may be configured based on RV 0. The second signal may be configured based on RV 3. The third signal may be configured based on RV 2. The fourth signal may be configured based on RV 1. For example, the first signal may be configured based on RV 0. The second signal may be configured based on RV 3. The third signal may be configured based on RV 1. The fourth signal may be configured based on RV 2. For example, the first signal may be configured based on RV 0. The second signal may be configured based on RV 1. The third signal may be configured based on RV 2. The fourth signal may be configured based on RV 3. For example, the first signal may be configured based on RV 0. The second signal may be configured based on RV 2. The third signal may be configured based on RV 1. The fourth signal may be configured based on RV 3. For example, the first signal may be configured based on RV 0. The second signal may be configured based on RV 1. The third signal may be configured based on RV 3. The fourth signal may be configured based on RV 2.

For example, a size of the soft buffer may be set based on a lifting size Z. for a low density parity check (LDPC).

For example, the entire area of the soft buffer may be configured as an address 0 to an address 65×Z_{c}. The first area may be configured as an address 0 to an address 23×Z_{c}. The second area may be configured as an address 33×Z_{c} to an address 56×Z_{c}. The third area may be configured as an area of an address 0 to an address 13×Z_{c} and an area of an address 56×Z_{c} to an address 65×Z_{c}. The fourth area may be configured as an address 17×Z_{c} to an address 40×Z_{c}.

For example, the first area to the fourth area may be indicated based on a continuous first section, a continuous second section, and an offset.

For example, the electronic device may identify that the second signal is associated with the retransmission of the transport block based on a value of a new data indicator (NDI) for the first signal and a value of the NDI for the second signal being the same.

In operation 1830 to operation 1860, an operation of the electronic device storing the second data on the second signal in the soft buffer and then decoding the first combined data obtained based on combining the first data and the second data is illustrated, but is not limited thereto.

For example, the electronic device may obtain the first combined data based on combining the first data and the second data without storing the second data in the soft buffer. The electronic device may store the second data in the soft buffer based on the failure to decode the first combined data.

According to an embodiment of the disclosure, the soft buffer may be divided into a first soft buffer (e.g., a circular buffer) and a second soft buffer (e.g., HARQ LLR memory). For example, the first soft buffer and the second soft buffer may be configured identically.

For example, the first soft buffer may be used for decoding data. The second soft buffer may be used to store data (e.g., the first data) related to a previously transmitted signal (e.g., the first signal). The electronic device may store the first data in the first soft buffer based on receiving the first signal. The electronic device may decode the first data using the first soft buffer. The electronic device may store (or write) the first data in the second soft buffer based on a failure to decode the first data. The electronic device may obtain (or read) the first data stored in the second soft buffer based on reception of the second signal. The electronic device may store the first data in the first soft buffer. The electronic device may store the second data related to the second signal in the first soft buffer. The electronic device may perform decoding of the first combined data obtained based on combining the first data and the second data by using the first soft buffer.

For example, the electronic device may store the second data in the second soft buffer. For example, the first data may be stored in a first area of the second soft buffer (or the first soft buffer). The second data may be stored in a second area of the second soft buffer (or the first soft buffer).

Although an operation by an entity (e.g., the electronic device) has been described in FIG. 18, embodiments of the disclosure are not limited thereto. The above-described operations may be performed by network entities (e.g., DU, and RU) of the base station 110 in a distributed network. For example, the reception operation of operations 1810 and 1830 may include a reception operation of the DU through the RU.

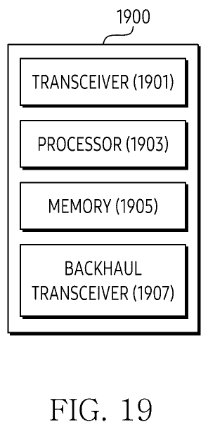

FIG. 19 illustrates a functional configuration of an electronic device according to an embodiment of the disclosure.

Referring to FIG. 19, an electronic device 1900 may include a transceiver 1901, a processor 1903, memory 1905, and a backhaul transceiver 1907.

The transceiver 1901 may perform functions for transmitting and receiving signals in a wired communication environment. The transceiver 1901 may include a wired interface for controlling a direct connection between a device and a device through a transmission medium (e.g., copper wire, or optical fiber). For example, the transceiver 1901 may transmit an electrical signal to another device through the copper wire, or may perform conversion between the electrical signal and an optical signal.

The transceiver 1901 may perform functions for transmitting and receiving signals in a wireless communication environment. For example, the transceiver 1901 may perform a conversion function between a baseband signal and a bit stream according to a physical layer specification of a system. For example, when transmitting data, the transceiver 1901 generates complex-valued symbols by encoding and modulating a transmission bit stream. In addition, when receiving data, the transceiver 1901 restores a reception bit stream by demodulating and decoding the baseband signal. In addition, the transceiver 1901 may include a plurality of transmission/reception paths.

The transceiver 1901 transmits and receives signals as described above. Accordingly, all or part of the transceiver 1901 may be referred to as a ‘communication unit’, a ‘transmission unit’, a ‘reception unit’, or a ‘transmission/reception unit’. In addition, in the following description, transmission and reception performed through a wireless channel are used to include the processing performed as described above by the transceiver 1901.

The processor 1903 controls overall operations of the electronic device 1900. The processor 1903 may be referred to as a control unit. For example, the processor 1903 transmits and receives signals through transceiver 1901 (or through the backhaul transceiver 1907). In addition, the processor 1903 writes and reads data in the memory 1905. In addition, the processor 1903 may perform functions of a protocol stack required by a communication standard. Although only the processor 1903 is illustrated in FIG. 19, according to another implementation, the electronic device 1900 may include two or more processors.

In the disclosure, the operations of the processor 1903 may mean being executed by software or controlling hardware components, such as a field programmable gate array (FPGA) or an application-specific integrated circuit (ASIC). In addition, the processor 1903 may include at least one of components, such as software components, object-oriented software components, class components, and task components, and processes, functions, properties, procedures, sub-routines, segments of program code, drivers, firmware, microcode, circuitry, data, database, data structures, tables, arrays, and variables. The processor 1903 may include at least one module, and the term “module” includes a unit configured with hardware, software, or firmware. For example, the module may be used interchangeably with terms, such as logic, logical block, component, or circuitry, and the like. The module may be an integrated component or a minimum unit performing one or more functions, or a portion thereof. For example, the module may be configured with ASIC.

The memory 1905 stores data, such as a basic program, an application program, and setting information for an operation of the electronic device 1900. The memory 1905 may be referred to as a storage unit. The memory 1905 may be configured with volatile memory, non-volatile memory, or a combination of the volatile memory and the non-volatile memory. In addition, the memory 1905 provides stored data according to a request of the processor 1903.

The electronic device 1900 may further include the backhaul transceiver 1907 for being connected to a core network or another base station. The backhaul transceiver 1907 provides an interface for performing communication with other nodes in a network. In other words, the backhaul transceiver 1907 converts a bit stream transmitted from a base station to another node, for example, another access node, another base station, an upper node, a core network, and the like, into a physical signal, and converts the physical signal received from the other node into the bit stream.

According to an embodiment of the disclosure, at least some of operations to be described below may be performed by one network entity of the electronic device 1900, and remaining operations may be performed by another network entity of the electronic device 1900. For example, an operation in which the electronic device 1900 receives a signal may be performed by an entity (e.g., RU) of the electronic device 1900. An operation in which the electronic device 1900 decodes a signal may be performed by another network entity (e.g., DU) of the electronic device 1900. An operation of determining a retransmission by the electronic device 1900 may be performed by another network entity of the electronic device 1900. An operation of generating DCI by the electronic device 1900 may be performed by another network entity of the electronic device 1900. An operation of storing HARQ LLR data in the soft buffer by the electronic device 1900 may be performed by another network entity of the electronic device 1900.

According to an embodiment of the disclosure, a method performed by an electronic device may comprise receiving a first signal related to an initial transmission of a transport block. The method may comprise, based on a failure to decode the first signal, storing first data related to the first signal in a soft buffer of the electronic device. The method may comprise receiving a second signal related to a retransmission of the transport block. The method may comprise storing second data related to the second signal in the soft buffer. The method may comprise identifying, among the soft buffer, a first area for the first data and a second area for the second data, distinguished from an area in which data is not stored, as a decoding area. The method may comprise, based on the decoding area, performing decoding of first combined data obtained based on combining the first data and the second data.

According to an embodiment of the disclosure, the method may comprise, based on a failure to decode the first combined data, receiving a third signal related to a second retransmission of the transport block. The method may comprise storing third data related to the third signal in a third area of the soft buffer. The method may comprise changing the decoding area to an area excluding any area in which data is not stored from an entire area. The method may comprise, based on the decoding area, decoding second combined data obtained based on combining the first data to the third data.

According to an embodiment of the disclosure, the third area may comprise at least a portion of the second area.

According to an embodiment of the disclosure, the method may comprise, based on a failure to decode the second combined data, receiving a fourth signal related to a third retransmission of the transport block. The method may comprise storing fourth data related to the fourth signal in a fourth area of the soft buffer. The method may comprise changing the decoding area to an entire area of the soft buffer. The method may comprise, based on the decoding area, decoding third combined data obtained based on combining the first data to the fourth data.

According to an embodiment of the disclosure, the fourth area may comprise at least a portion of the first area and at least a portion of the second area.

According to an embodiment of the disclosure, the first signal may be configured based on a redundancy version (RV) 0. The second signal may be configured based on RV 2. The third signal may be configured based on RV 3. The fourth signal may be configured based on RV 1.

According to an embodiment of the disclosure, a size of the soft buffer may be configured based on a lifting size (Z_{c}) related to low density parity check (LDPC).

According to an embodiment of the disclosure, the entire area of the soft buffer may be configured as an address 0 to an address 65×Z_{c}. The first area may be configured as an address 0×Z_{c} to an address 23×Z_{c}. The second area may be configured as an address 33×Z_{c} to an address 56×Z_{c}. The third area may be configured as an area of an address 0×Z_{c} to an address 13×Z_{c} and an area of an address 56×Z_{c} to an address 65×Z_{c}. The fourth area may be configured as an area of an address 17×Z_{c} to an address 40×Z_{c}.

According to an embodiment of the disclosure, the first area to the fourth area may be indicated based on a continuous first section, a continuous second section, and an offset.

The method may comprise identifying that the second signal is associated with the retransmission of the transport block based on a value of a new data indicator (NDI) for the first signal and a value of the NDI for the second signal being the same.

According to an embodiment of the disclosure, an electronic device may comprise memory, a transceiver, and at least one processor operably coupled with the memory and the transceiver. The at least one processor may be configured to receive a first signal related to an initial transmission of a transport block. The at least one processor may be configured to, based on a failure to decode the first signal, store first data related to the first signal in a soft buffer of the electronic device. The at least one processor may be configured to receive a second signal related to a retransmission of the transport block. The at least one processor may be configured to store second data related to the second signal in the soft buffer. The at least one processor may be configured to identify, among the soft buffer, a first area for the first data and a second area for the second data, distinguished from an area in which data is not stored, as a decoding area. The at least one processor may be configured to, based on the decoding area, perform decoding of first combined data obtained based on combining the first data and the second data.

According to an embodiment of the disclosure, the at least one processor may be configured to, based on a failure to decode the first combined data, receive a third signal related to a second retransmission of the transport block. The at least one processor may be configured to store third data related to the third signal in a third area of the soft buffer. The at least one processor may be configured to change the decoding area to an area excluding any area in which data is not stored from an entire area. The at least one processor may be configured to, based on the decoding area, decode second combined data obtained based on combining the first data to the third data.

According to an embodiment of the disclosure, the third area may comprise at least a portion of the second area.

According to an embodiment of the disclosure, the at least one processor may be configured to, based on a failure to decode the second combined data, receive a fourth signal related to a third retransmission of the transport block. The at least one processor may be configured to store fourth data related to the fourth signal in a fourth area of the soft buffer. The at least one processor may be configured to change the decoding area to an entire area of the soft buffer. The at least one processor may be configured to, based on the decoding area, decode third combined data obtained based on combining the first data to the fourth data.

According to an embodiment of the disclosure, the fourth area may comprise at least a portion of the first area and at least a portion of the second area.

According to an embodiment of the disclosure, the first signal may be configured based on a redundancy version (RV) 0. The second signal may be configured based on RV 2. The third signal may be configured based on RV 3. The fourth signal may be configured based on RV 1.

According to an embodiment of the disclosure, a size of the soft buffer may be configured based on a lifting size (Z_{c}) related to low density parity check (LDPC).

According to an embodiment of the disclosure, the entire area of the soft buffer may be configured as an address 0 to an address 65×Z_{c}. The first area may be configured as an address 0×Z_{c} to an address 23×Z_{c}. The second area may be configured as an address 33×Z_{c} to an address 56 ×Z_{c}. The third area may be configured as an area of an address 0×Z_{c} to an address 13×Z_{c} and an area of an address 56×Z_{c} to an address 65 × Z_{c}. The fourth area may be configured as an area of an address 17×Z_{c} to an address 40 ×Z_{c}.

According to an embodiment of the disclosure, the first area to the fourth area may be indicated based on a continuous first section, a continuous second section, and an offset.

According to an embodiment of the disclosure, the at least one processor may be configured to identify that the second signal is associated with the retransmission of the transport block, based on a value of a new data indicator (NDI) for the first signal and a value of the NDI for the second signal being the same.

According to an embodiment of the disclosure, a non-transitory computer readable storage media may store one or more programs. The one or more programs may comprise instructions which, when executed by a processor of an electronic device with a transceiver, cause the electronic device to receive a first signal related to an initial transmission of a transport block, based on a failure to decode the first signal. The one or more programs may comprise instructions which, when executed by the processor of the electronic device, cause the electronic device to store first data related to the first signal in a soft buffer of the electronic device. The one or more programs may comprise instructions which, when executed by the processor of the electronic device, cause the electronic device to receive a second signal related to a retransmission of the transport block. The one or more programs may comprise instructions which, when executed by the processor of the electronic device, cause the electronic device to store second data related to the second signal in the soft buffer. The one or more programs may comprise instructions which, when executed by the processor of the electronic device, cause the electronic device to identify, among the soft buffer, a first area for the first data and a second area for the second data, distinguished from an area in which data is not stored, as a decoding area. The one or more programs may comprise instructions which, when executed by the processor of the electronic device, cause the electronic device to, based on the decoding area, perform decoding of first combined data obtained based on combining the first data and the second data.

Methods according to embodiments of the disclosure described in claims or specifications of the disclosure may be implemented as a form of hardware, software, or a combination of hardware and software.

In a case of implementing as software, a computer-readable storage medium for storing one or more programs (software module) may be provided. The one or more programs stored in the computer-readable storage medium are configured for execution by one or more processors in an electronic device. The one or more programs include instructions that cause the electronic device to execute the methods according to embodiments described in claims or specifications of the disclosure. The one or more programs may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. In the case of being distributed online, at least part of the computer program product may be temporarily generated or at least temporarily stored in the machine-readable storage medium, such as memory of the manufacturer's server, the application store's server, or a relay server.

Such a program (software module, software) may be stored in random access memory, non-volatile memory including flash memory, read only memory (ROM), electrically erasable programmable read only memory (EEPROM), magnetic disc storage device, compact disc-ROM (CD-ROM), optical storage device (digital versatile discs (DVDs) or other formats), or a magnetic cassette. Alternatively, it may be stored in memory configured with a combination of some or all of them. In addition, a plurality of configuration memories may be included.

Additionally, a program may be stored in an attachable storage device that may be accessed through a communication network, such as the Internet, Intranet, local area network (LAN), wide area network (WAN), or storage area network (SAN), or a combination thereof. Such a storage device may be connected to a device performing an embodiment of the disclosure through an external port. In addition, a separate storage device on the communication network may also be connected to a device performing an embodiment of the disclosure.

In the above-described specific embodiments of the disclosure, components included in the disclosure are expressed in the singular or plural according to the presented specific embodiment. However, the singular or plural expression is selected appropriately according to a situation presented for convenience of explanation, and the disclosure is not limited to the singular or plural component, and even components expressed in the plural may be configured in the singular, or a component expressed in the singular may be configured in the plural.

According to various embodiments of the disclosure, one or more components or operations of the above-described components may be omitted, or one or more other components or operations may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to various embodiments of the disclosure, operations performed by the module, the program, or another component may be executed sequentially, in parallel, repeatedly, or heuristically, or one or more of the operations may be executed in a different order or omitted, or one or more other operations may be added.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A method performed by an electronic device, the method comprising:
receiving a first signal related to an initial transmission of a transport block;
based on a failure to decode the first signal, storing first data related to the first signal in a soft buffer of the electronic device;
receiving a second signal related to a retransmission of the transport block;
storing second data related to the second signal in the soft buffer;
identifying, among the soft buffer, a first area for the first data and a second area for the second data, distinguished from an area in which data is not stored, as a decoding area; and
based on the decoding area, performing decoding of first combined data obtained based on combining the first data and the second data.

2. The method of claim 1, further comprising:
based on a failure to decode the first combined data, receiving a third signal related to a second retransmission of the transport block;
storing third data related to the third signal in a third area of the soft buffer;
changing the decoding area to an area excluding any area in which data is not stored from an entire area; and
based on the decoding area, decoding second combined data obtained based on combining the first data to the third data.

3. The method of claim 2, wherein the third area comprises at least a portion of the second area.

4. The method of claim 2, further comprising:
based on a failure to decode the second combined data, receiving a fourth signal related to a third retransmission of the transport block;
storing fourth data related to the fourth signal in a fourth area of the soft buffer;
changing the decoding area to an entire area of the soft buffer; and
based on the decoding area, decoding third combined data obtained based on combining the first data to the fourth data.

5. The method of claim 4, wherein the fourth area comprises at least a portion of the first area and at least a portion of the second area.

6. The method of claim 5,
wherein the first signal is configured based on a redundancy version (RV) 0,
wherein the second signal is configured based on RV 2,
wherein the third signal is configured based on RV 3, and
wherein the fourth signal is configured based on RV 1.

7. The method of claim 4, wherein a size of the soft buffer is configured based on a lifting size (Z_{c}) related to low density parity check (LDPC).

8. The method of claim 7,
wherein the entire area of the soft buffer is configured as an address 0 to an address 65×Z_{c},
wherein the first area is configured as an address 0×Z_{c} to an address 23×Z_{c},
wherein the second area is configured as an address 33×Z_{c} to an address 56×Z_{c},
wherein the third area is configured as an area of an address 0×Z_{c} to an address 13×Z_{c} and an area of an address 56×Z_{c} to an address 65×Z_{c}, and
wherein the fourth area is configured as an area of an address 17×Z_{c} to an address 40×Z_{c}.

9. The method of claim 1, wherein the first area to the fourth area are indicated based on a continuous first section, a continuous second section, and an offset.

10. The method of claim 1, further comprising identifying that the second signal is associated with the retransmission of the transport block based on a value of a new data indicator (NDI) for the first signal and a value of the NDI for the second signal being the same.

11. An electronic device comprising:
memory, comprising one or more storage media, storing instructions;
a transceiver; and
at least one processor communicatively coupled to the memory and the transceiver,
wherein the instructions, when executed by the at least one processor individually or collectively, cause the electronic device to:
receive a first signal related to an initial transmission of a transport block,
based on a failure to decode the first signal, store first data related to the first signal in a soft buffer of the electronic device,
receive a second signal related to a retransmission of the transport block,
store second data related to the second signal in the soft buffer,
identify, among the soft buffer, a first area for the first data and a second area for the second data, distinguished from an area in which data is not stored, as a decoding area, and
based on the decoding area, perform decoding of first combined data obtained based on combining the first data and the second data.

12. The electronic device of claim 11, wherein the instructions, when executed by the at least one processor individually or collectively, further cause the electronic device to:
based on a failure to decode the first combined data, receive a third signal related to a second retransmission of the transport block,
store third data related to the third signal in a third area of the soft buffer,
change the decoding area to an area excluding any area in which data is not stored from an entire area, and
based on the decoding area, decode second combined data obtained based on combining the first data to the third data.

13. The electronic device of claim 12, wherein the third area comprises at least a portion of the second area.

14. The electronic device of claim 12, wherein the instructions, when executed by the at least one processor individually or collectively, further cause the electronic device to:
based on a failure to decode the second combined data, receive a fourth signal related to a third retransmission of the transport block,
store fourth data related to the fourth signal in a fourth area of the soft buffer,
change the decoding area to an entire area of the soft buffer, and
based on the decoding area, decode third combined data obtained based on combining the first data to the fourth data.

15. The electronic device of claim 14, wherein the fourth area comprises at least a portion of the first area and at least a portion of the second area.

16. The electronic device of claim 15,
wherein the first signal is configured based on a redundancy version (RV) 0,
wherein the second signal is configured based on RV 2,
wherein the third signal is configured based on RV 3, and
wherein the fourth signal is configured based on RV 1.

17. The electronic device of claim 14, wherein a size of the soft buffer is configured based on a lifting size (Z_{c}) related to low density parity check (LDPC).

18. The electronic device of claim 17,
wherein the entire area of the soft buffer is configured as an address 0 to an address 65×Z_{c},
wherein the first area is configured as an address 0×Z_{c} to an address 23×Z_{c},
wherein the second area is configured as an address 33×Z_{c} to an address 56×Z_{c},
wherein the third area is configured as an area of an address 0×Z, to an address 13×Z_{c} and an area of an address 56×Z_{c} to an address 65×Z_{c}, and
wherein the fourth area is configured as an area of an address 17×Z_{c} to an address 40×Z_{c}.

19. The electronic device of claim 11, wherein the first area to the fourth area are indicated based on a continuous first section, a continuous second section, and an offset.

20. A non-transitory computer readable storage media storing one or more programs, wherein the one or more programs comprise instructions which, when executed by a processor of an electronic device with a transceiver, cause the electronic device to:
receive a first signal related to an initial transmission of a transport block,
based on a failure to decode the first signal, store first data related to the first signal in a soft buffer of the electronic device,
receive a second signal related to a retransmission of the transport block,
store second data related to the second signal in the soft buffer,
identify, among the soft buffer, a first area for the first data and a second area for the second data, distinguished from an area in which data is not stored, as a decoding area, and
based on the decoding area, perform decoding of first combined data obtained based on combining the first data and the second data.
